(19) United States
(12) Patent Application Publication
(10) Pub. No.: US 2026/0165200 A1
(43) Pub. Date: Jun. 11, 2026

(54) PASSIVE SEMICONDUCTOR DEVICE WITH SHIFTED STACKED FIELD EFFECT TRANSISTOR

(71) Applicant: INTERNATIONAL BUSINESS MACHINES CORPORATION, ARMONK, NY (US)

(72) Inventors: Robert Gauthier, Williston, VT (US); Ruilong Xie, Niskayuna, NY (US); Masoud Zabihi, Schenectady, NY (US); Anindya Nath, Watervliet, NY (US); Anthony I-Chih Chou, Guilderland, NY (US)

(21) Appl. No.: 18/976,230

(22) Filed: Dec. 10, 2024

(51) Int. Cl. H01L 25/07; H01L 23/00; H01L 23/48; H10D 89/60

(52) U.S. Cl. CPC H10W 90/00; H10D 89/713; H10W 20/20; H10W 90/732

(57) ABSTRACT

A semiconductor device includes a passive device region having a first source/drain region, a second source/drain region, a frontside contact over the first source/drain region, a backside contact below the second source/drain region, and a bonding oxide bonding the first source/drain region and the second source/drain region to a backside interlayer dielectric.

### BACKGROUND

### Technical Field

The present disclosure generally relates to semiconductors, and more particularly, to passive semiconductor device with shifted stacked field effect transistor structure, and methods of creation thereof.

### Description of Related Art

The continuous miniaturization of transistors and their increasing density on chips epitomize the semiconductor industry's innovation, largely adhering to Moore's Law. This trend has led to transistors shrinking to nanometer scales, allowing millions and even billions to fit on a single chip, significantly enhancing computational power and energy efficiency. The evolution towards system-on-chip architectures integrates various functionalities, including processing and sensing, on one chip.

### SUMMARY

According to an embodiment, a semiconductor device includes a passive device region having a first source/drain region, a second source/drain region, a frontside contact over the first source/drain region, a backside contact below the second source/drain region, and a bonding oxide bonding the first source/drain region and the second source/drain region to a backside interlayer dielectric.

In one embodiment, the semiconductor includes a first doped region and a second doped region between the first source/drain region and the second source/drain region, and an interlayer dielectric over the first doped region, the second doped region, the first source/drain region and the second source/drain region.

In one embodiment, the second source/drain region is at least partially extended within the bonding oxide.

In one embodiment, the first doped region is doped with a same type of dopant as the second source/drain region, and the second doped region is doped with a same type of dopant as the first source/drain region.

In one embodiment, the semiconductor includes a doped region between the first source/drain region and the second source/drain region. The first source/drain region and the second source/drain region are doped with a different type of dopant, the doped region is doped with a same dopant as the first source/drain region.

In one embodiment, the semiconductor includes a doped region between the first source/drain region and the second source/drain region. The first source/drain region and the second source/drain region are doped with a different type of dopant, the doped region is doped with a same dopant as the second source/drain region.

In one embodiment, the semiconductor includes a doped region between the first source/drain region and the second source/drain region. The first source/drain region and the second source/drain region are doped with a same type of dopant, the doped region is doped with a different dopant as the first source/drain region and the second source/drain region.

In one embodiment, the passive device region is an N+/n-well/P-well/P+ diode.

In one embodiment, the semiconductor includes a logic region having a top transistor including a first top source/drain region, a second top transistor gate region, a first backside contact connecting the second top source/drain region to a backside of the logic region, and a frontside source/drain contact over the first top source/drain region, and a bottom transistor including a first bottom source/drain region, a second bottom transistor gate region, and a second backside source/drain contact below the second bottom source/drain region, and a bonding oxide separating the top transistor and the bottom transistor.

In one embodiment, the semiconductor includes a via connecting the first bottom source/drain region to a back end of line on a frontside of the logic region.

According to an embodiment, a method for fabrication of a semiconductor device includes forming a passive device region having a first source/drain region, a second source/drain region, a frontside contact over the first source/drain region a backside contact below the second source/drain region, and a bonding oxide bonding the first source/drain region and the second source/drain region to a backside interlayer dielectric.

In one embodiment, the method includes forming a first doped region and a second doped region between the first source/drain region and the second source/drain region, and forming an interlayer dielectric over the first doped region, the second doped region, the first source/drain region and the second source/drain region.

In one embodiment, the method includes extending partially the second source/drain region within the bonding oxide.

In one embodiment, the method includes doping the first doped region with a same type of dopant as the second source/drain region, doping the second doped region with a same type of dopant as the first source/drain region.

In one embodiment, the method includes forming a doped region between the first source/drain region and the second source/drain region, doping the first source/drain region and the second source/drain region with a different type of dopant, and doping the doped region with a same dopant as the first source/drain region.

In one embodiment, the method includes forming a doped region between the first source/drain region and the second source/drain region, doping the first source/drain region and the second source/drain region are doped with a different type of dopant, and doping the doped region is doped with a same dopant as the second source/drain region.

In one embodiment, the method includes forming a doped region between the first source/drain region and the second source/drain region, forming the first source/drain region and the second source/drain region are doped with a same type of dopant, and forming the doped region is doped with a different dopant as the first source/drain region and the second source/drain region.

In one embodiment, the method includes forming a logic region having a top transistor including forming a first top source/drain region, forming a second top transistor gate region, forming a first backside contact connecting the second top source/drain region to a backside of the logic region, and forming a frontside source/drain contact over the first top source/drain region, and forming a bottom transistor including forming a first bottom source/drain region, forming a second bottom transistor gate region, and forming a second backside source/drain contact below the second bottom source/drain region, and forming a bonding oxide separating the top transistor and the bottom transistor

In one embodiment, the method includes establishing an electrical between the first bottom source/drain region and a back end of line on a frontside of the logic region through a via.

According to an embodiment, a semiconductor device includes a logic region having a top transistor, and a bottom, and a passive device region having a first source/drain region, a second source/drain region, and a bonding oxide bonding the first source/drain region and the second source/drain region to a backside interlayer dielectric.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A is a conceptual schematic diagram of an ESD device.

FIG. 1B illustrates different operation regions of an ESD device, including during the normal circuit operation voltage range, ESD operating window during an ESD event, and the failure region of the diagram of FIG. 1A.

FIG. 1C illustrates a conventional planar semiconductor device with shallow trench isolation.

FIGS. 1D-1E illustrate circuitry of the semiconductor device shown in FIG. 1C.

FIG. 1F illustrates an I-V curve of the semiconductor device shown in FIG. 1C.

FIGS. 2A-2B illustrate conventional electrostatic discharge devices with shallow trench isolation.

FIG. 3A illustrates a set of diodes with an N-well and P-well top diode layer, in accordance with some embodiments.

FIG. 3B illustrates a top view of a set of diodes with an N-well and P-well region top diode layer, in accordance with some embodiments.

FIG. 4A illustrates a set of diodes with an N-well and P-doped region top diode layer, in accordance with some embodiments.

FIG. 4B illustrates a top view of a set of diodes with an N-well and P-doped region top diode layer, in accordance with some embodiments.

FIG. 5A illustrates a set of diodes with an N-doped region/P-well top diode layer, in accordance with some embodiments.

FIG. 5B illustrates a top view of a set of diodes with an N-doped region/P-well top diode layer, in accordance with some embodiments.

FIG. 6A illustrates a set of diodes with an N-doped region/P-well/N-doped region top diode layer, in accordance with some embodiments.

FIG. 6B illustrates a top view of a set of diodes with an N-doped region/P-well/N-doped region top diode layer, in accordance with some embodiments.

FIG. 7A illustrates a set of diodes with a P-doped region/N-well/P-well, in accordance with some embodiments.

FIG. 7B illustrates a top view of a set of diodes with P-doped region/N-well/P-well, in accordance with some embodiments.

FIG. 8A illustrates a set of diodes with a P-doped region/N-well/P-well/N-doped region, in accordance with some embodiments.

FIG. 8B illustrates a top view of a set of diodes with P-doped region/N-well/P-well/N-doped region, in accordance with some embodiments.

FIGS. 9A-9B illustrate a semiconductor device after the formation of the bottom layer, in accordance with some embodiments.

FIGS. 10A-10B illustrate a semiconductor device after the formation of the bonding oxide, in accordance with some embodiments.

FIGS. 11A-11B illustrate a semiconductor device after the formation of the stacks of nanosheet, in accordance with some embodiments.

FIGS. 12A-12B illustrate a semiconductor device after the removal of the top layers for passive device region, in accordance with some embodiments.

FIGS. 13A-13B illustrate a semiconductor device after the formation of the silicon layer on the passive device region, in accordance with some embodiments.

FIGS. 14A-14B illustrate a semiconductor device after the implantation of the passive device region, in accordance with some embodiments.

FIGS. 15A-15B illustrate a semiconductor device after the removal of the hard mask, in accordance with some embodiments.

FIGS. 16A-16B illustrate a semiconductor device after the formation of the bonding oxide on the top device, in accordance with some embodiments.

FIGS. 17A-17B illustrate a semiconductor device after the removal of the substrate, in accordance with some embodiments.

FIGS. 18A-18B illustrate a semiconductor device after the removal of the SiGe layer, in accordance with some embodiments.

FIGS. 19A-19B illustrate a semiconductor device after the formation of the top device, in accordance with some embodiments.

FIGS. 20A-20B illustrate a semiconductor device after the formation of the frontside interconnect and carrier wafer bonding, in accordance with some embodiments.

FIGS. 21A-21B illustrate a semiconductor device after the removal of the substrate, in accordance with some embodiments.

FIGS. 22A-22B illustrate a semiconductor device after the removal of the sacrificial placeholders, in accordance with some embodiments.

FIGS. 23A-23B illustrate a semiconductor device after the formation of the backside interconnect, in accordance with some embodiments.

FIG. 24 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter can be combined with elements of different embodiments.

In foundry technology, designing electrostatic discharge (ESD) protection devices requires addressing the diverse needs of typical input/output (I/O) configurations. These devices should meet stringent requirements to ensure robust protection against voltage spikes caused by ESD events while maintaining compatibility with the I/O types commonly used in advanced semiconductor technologies. The main categories of ESD devices for such applications include vertical bipolar transistors, lateral bipolar transistors, thyristors (also known as silicon-controlled rectifiers, SCRs), and power supply clamps. Each of these device types plays a distinct role in safeguarding sensitive circuits, depending on the application and performance requirements.

Vertical bipolar transistors are widely used in ESD protection circuits due to their ability to handle high current densities efficiently. Their vertically stacked structure allows current to flow perpendicularly to the plane of the substrate, enabling compact device layouts that can dissipate significant amounts of energy during an ESD event. These devices are typically implemented as NPN or PNP transistors, depending on the specific requirements of the circuit. Vertical bipolars are particularly advantageous in applications requiring high-speed protection and efficient integration into multi-layered semiconductor devices.

Lateral bipolar transistors offer an alternative approach, with current flowing parallel to the surface of the substrate. This lateral configuration provides greater flexibility in layout design and is often used in planar processes where space constraints or integration with other planar devices are priorities. Lateral bipolars are commonly employed in scenarios where high-speed response and precise control of the ESD protection mechanism are critical. Their planar nature also makes them well-suited for integration in standard CMOS technologies.

Thyristors, such as NPNP or PNPN configurations, are another component of ESD protection strategies. These devices operate as controlled switches that latch into a low-resistance state when triggered, allowing them to conduct large amounts of current away from sensitive circuit areas. Thyristors are especially effective for applications requiring high-current handling capabilities, making them suitable for protecting power-intensive I/O lines or circuits prone to high-voltage transients. The inherent current-limiting and latching characteristics of thyristors ensure that the device can respond effectively to sudden surges without impacting normal circuit operation.

Power supply clamps are one category of ESD protection devices, typically designed using circuits with wide field-effect transistors (FETs). These clamps act as voltage regulators during ESD events, providing a low-resistance path between power rails to shunt excess energy safely. The use of wide FETs in these clamps allows for higher current-carrying capacity, ensuring that power rails are effectively protected from overvoltage conditions. Power supply clamps are critical for safeguarding the integrity of the power distribution network within semiconductor devices, especially in high-density integrated circuits where stable power delivery is essential.

Together, these device types provide a comprehensive set of tools for addressing the diverse challenges posed by ESD protection in foundry technologies. By combining vertical and lateral bipolar transistors, thyristors, and power supply clamps, designers can create robust protection schemes tailored to the unique requirements of modern semiconductor applications, ensuring reliable performance and longevity of the devices.

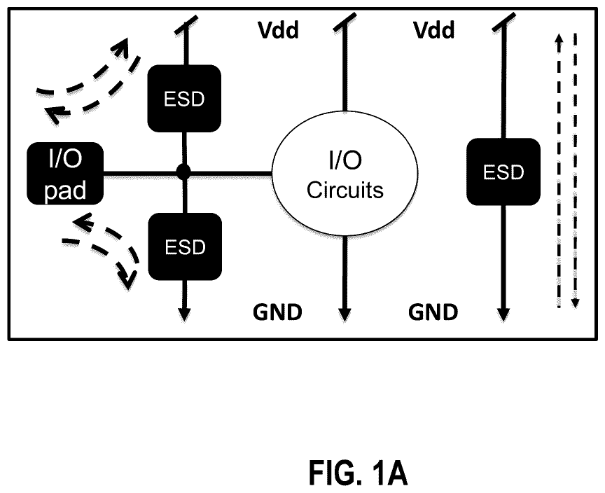

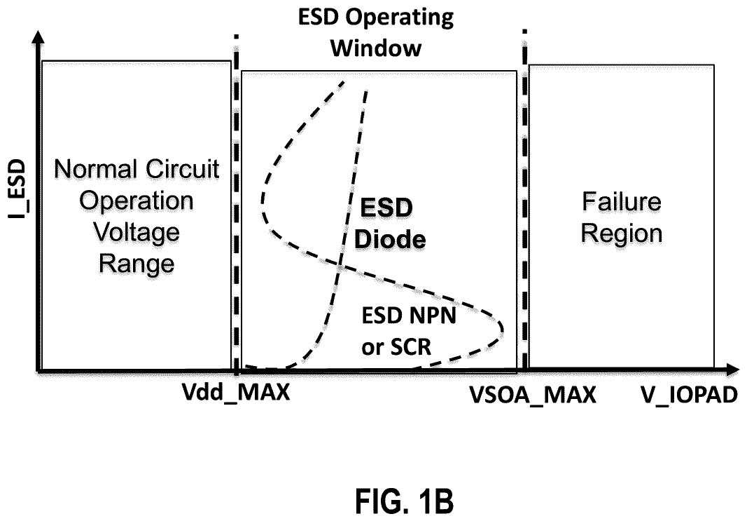

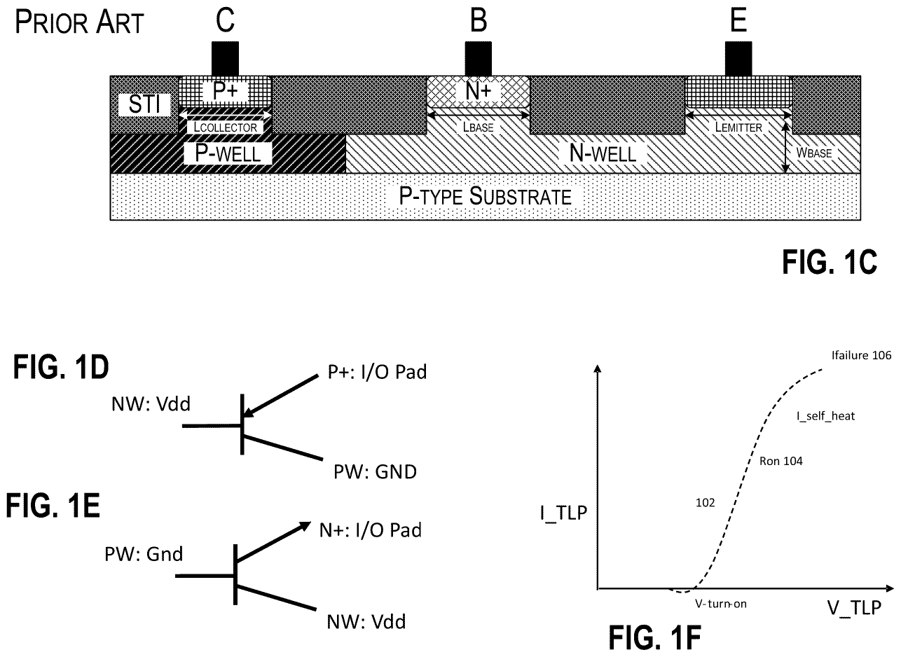

FIG. 1C illustrates a conventional planar semiconductor device with shallow trench isolation. FIGS. 1D-1E illustrate circuitry of the semiconductor device shown in FIG. 1C. FIG. 1F illustrates an I-V curve of the semiconductor device shown in FIG. 1C.

A Planar CMOS shallow trench isolation (STI)-bound PNP transistor operates by enabling controlled current flow from the emitter to the collector through the base. This type of bipolar junction transistor (BJT) uses STI regions for electrical isolation, ensuring that the current paths are confined to specific regions within the transistor. The transistor is designed for compatibility with planar CMOS processes, making it suitable for high-density integrated circuits. In a PNP transistor, the emitter is a heavily doped P-type region that injects holes into the N-type base when a forward bias is applied across the base-emitter junction. The base, being lightly doped and thinner than the emitter, allows the majority of the injected holes to diffuse through it without significant recombination. These holes are then collected by the moderately doped P-type collector, completing the current flow through the transistor. The operation depends on maintaining the correct forward bias voltage across the base-emitter junction, typically requiring the base to be slightly negative relative to the emitter.

The STI regions are insulating trenches that surround the emitter, base, and collector. The trenches are filled with a dielectric material, such as silicon dioxide, to isolate the transistor electrically from adjacent devices in the circuit. The isolation prevents leakage currents and reduces (e.g., minimizes) parasitic effects that could interfere with the transistor's operation. The STI ensures that the current flow remains within the intended regions of the transistor, enhancing its efficiency and reliability. Contacts for the emitter, base, and collector are positioned on the surface of the semiconductor device, allowing external connections to the transistor. The contacts are connected through interconnect layers, which are carefully aligned to the respective regions of the transistor. The STI provides a physical barrier, helping to ensure that these connections do not short-circuit or interfere with neighboring components.

The functionality of this transistor extends to its integration within CMOS processes, allowing it to coexist with other planar CMOS devices. The planar design, combined with STI isolation, enhances its performance by reducing parasitic capacitance and ensuring that the device operates effectively within the confines of a densely packed semiconductor layout. This configuration makes the STI-bound PNP transistor, or its NPN counterpart, a versatile choice for various applications, including analog circuits, mixed-signal designs, and ESD protection.

The I-V graph of the ESDVPNP_STI begins with a region of minimal current flow, representing the leakage state. At voltages below the trigger threshold, the device remains in a high-impedance state, with only a small leakage current passing through, typically in the nanoampere range. The leakage region is characterized by a nearly flat curve close to the origin, where the voltage increases with negligible current flow. As the voltage reaches the trigger threshold, known as the trigger voltage or Vtrigger, the base-emitter junction of the vertical PNP structure becomes forward-biased. This causes the device to transition from a high-impedance state to a low-impedance state. The graph at this point, e.g., 102, shows a sharp rise in current, marking the onset of the trigger region. This steep transition indicates the rapid increase in current conduction, signaling the activation of the ESD protection mechanism.

Following the trigger point, the device enters the conduction or sustaining region. In this region, the device maintains a low-impedance state, allowing it to conduct high current while holding a relatively low voltage across its terminals. The voltage in this region stabilizes at a level known as the holding voltage or Vholding, which is lower than the trigger voltage. The slope of the curve in this region is determined by the device's on-resistance, Ron 104, with lower Ron values corresponding to more efficient current conduction. As the current or voltage continues to rise, the device approaches its maximum tolerances. Beyond a critical point, defined by the failure voltage Vfail 106 or failure current Ifail, the device enters the failure region. In this phase, the curve on the I-V graph shows a sharp drop in current, indicating the breakdown of the device's ability to sustain conduction. This may result from thermal overload, material breakdown, or other catastrophic failure mechanisms.

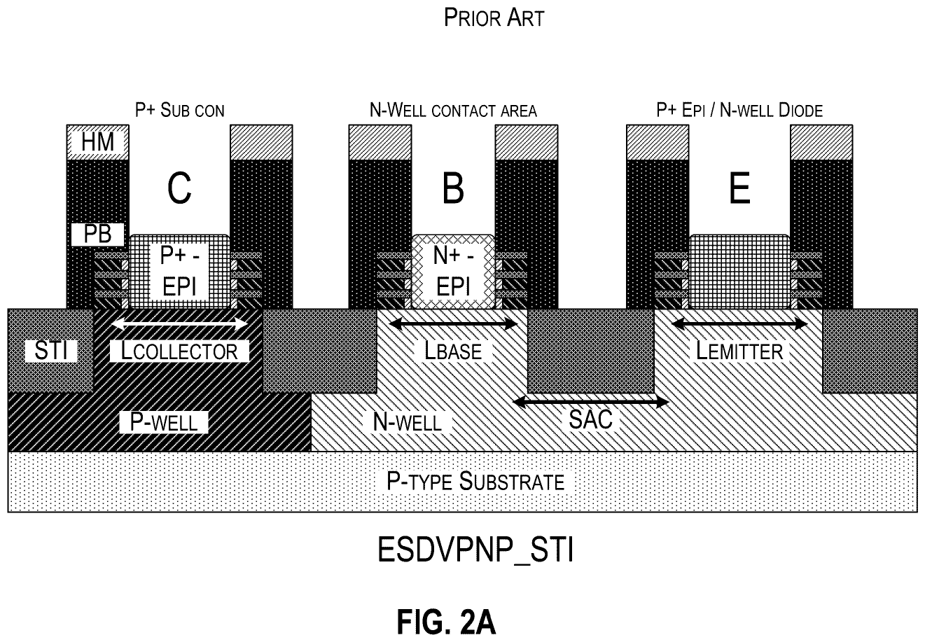

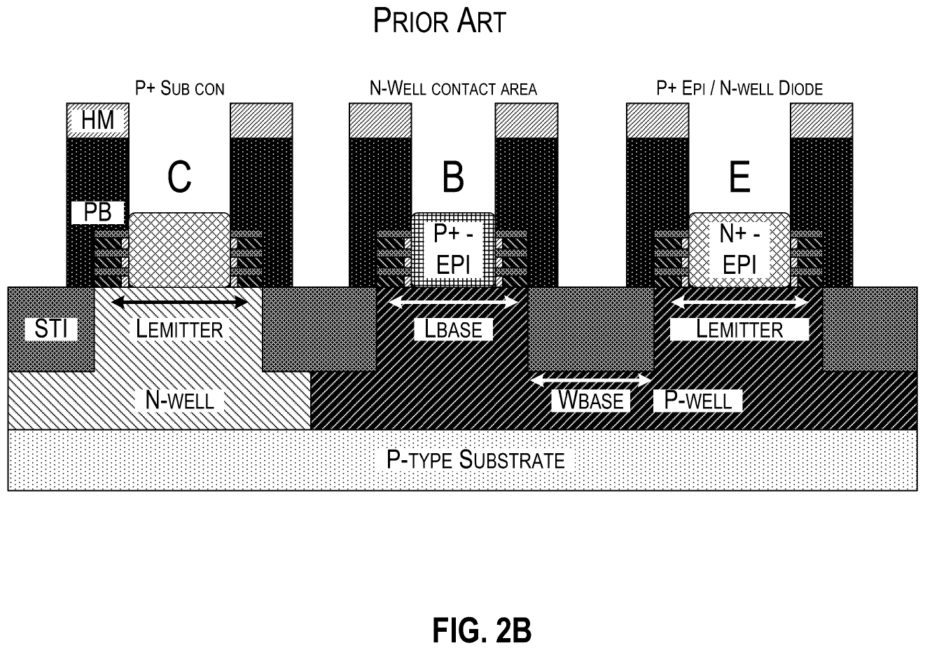

FIGS. 2A-2B illustrate conventional electrostatic discharge devices with shallow trench isolation. An ESD VPNP (Vertical PNP) and ESD VNPN (Vertical NPN) transistor with STI commonly referred to as ESDVPNP_STI and ESDVNPN_STI, are specialized bipolar junction transistors designed for electrostatic discharge (ESD) protection. Such devices leverage their vertical structure and STI isolation to efficiently handle high transient currents during ESD events while maintaining compactness and electrical isolation in semiconductor circuits.

The ESDVPNP_STI operates by facilitating current flow from a heavily doped P-type emitter, through a lightly doped N-type base, to a moderately doped P-type collector. During an ESD event, a sudden voltage spike forward-biases the base-emitter junction, allowing holes from the P-type emitter to be injected into the N-type base. The holes diffuse through the base and are collected by the P-type collector. The vertical configuration directs the current perpendicular to the plane of the substrate, which enables the device to conduct large amounts of current while reducing (e.g., minimizing) the space required. The STI surrounding the emitter, base, and collector provides electrical isolation, ensuring that the current flow is confined to the intended path and does not interfere with adjacent devices.

Similarly, the ESDVNPN_STI operates with electrons as the primary charge carriers. In this case, a heavily doped N-type emitter injects electrons into a lightly doped P-type base when the base-emitter junction is forward-biased during an ESD event. The electrons traverse the base and are collected by the moderately doped N-type collector. The vertical current flow, combined with the isolation provided by STI, ensures efficient conduction and effective dissipation of the high transient currents caused by the ESD pulse. By electrically isolating the emitter, base, and collector from adjacent components, STI prevents leakage currents and parasitic interactions that could degrade the performance of the device. The isolation also allows the ESDVPNP_STI and ESDVNPN_STI to be integrated seamlessly into dense semiconductor layouts without compromising reliability.

During an ESD event, these devices act as current conduits, rapidly transitioning from a high-impedance state to a low-impedance state to safely dissipate the surge energy. The vertical configuration ensures that the conduction path can handle large currents efficiently, reducing (e.g., minimizing) the risk of thermal or structural damage to the device. Once the ESD event subsides, the devices return to their high-impedance state, ready to protect the circuit again in future events. Both the ESDVPNP_STI and ESDVNPN_STI have the ability to manage high transient currents in a compact, isolated structure makes them suitable for use in advanced integrated circuits, ensuring robustness and reliability across a wide range of applications.

Disclosed is a semiconductor-controlled rectifier, SCR, integrated into a stacked field-effect transistor (FET) configuration with a nanosheet gate structure which combine the high-current handling capability of an SCR with the control and scalability of a nanosheet-based FET. This design leverages the complementary strengths of both components, resulting in an efficient semiconductor device suited for high-performance and high-density applications. The SCR, which is a four-layer device consisting of alternating P-type and N-type regions (e.g., P+/N−/P−/N+), forming two P-N junctions in series, can function as a controlled switch, transitioning from a high-impedance state to a low-impedance state when triggered.

In such a design, the SCR is integrated into a stacked FET architecture. The stacked FET can be vertically arranged transistors that improve (e.g., maximize) space efficiency by layering multiple FETs within a single device. Each FET in the stack includes a nanosheet gate structure, which is an ultra-thin, planar gate design that extends horizontally across the transistor channel. The nanosheet gates provide precise control over the current flow within the FET, offering enhanced switching speed and reduced power consumption compared to traditional gate structures. The integration of the SCR within the stacked FET configuration allows the FETs to act as the triggering mechanism for the SCR. For example, when a specific voltage threshold is applied to the nanosheet gate of one of the stacked FETs, it enables current flow that triggers the SCR to transition to its low-impedance state. Once triggered, the SCR conducts large currents efficiently, providing a safe pathway for energy dissipation or controlled current routing within the circuit.

The horizontal extension of the nanosheet gates allows for high gate control over the channel while maintaining a compact layout. The thin profile of the nanosheets improves the scalability of the device, making it suitable for advanced semiconductor nodes where reducing device dimensions is critical. Additionally, the nanosheet gates reduce the parasitic effects typically associated with larger gate structures, improving the speed and efficiency of the FETs and the overall device. By integrating an SCR into a stacked FET design with nanosheet gates, the semiconductor device achieves a unique combination of high-current capability, control, and scalability. The configuration is suitable for applications requiring protection, such as ESD, as well as power management in compact, high-density integrated circuits. The synergy between the SCR and the stacked nanosheet FETs allows for flexible operation, enabling the device to meet the demands of modern semiconductor applications with superior performance and reliability.

Accordingly, the teachings herein provide methods and systems of SCR formation in stacked transistors with nanosheet gate structures. The techniques described herein may be implemented in a number of ways. Example implementations are provided below with reference to the following figures.

### Example Passive Semiconductor Device in Shifted Stacked Transistors Structure

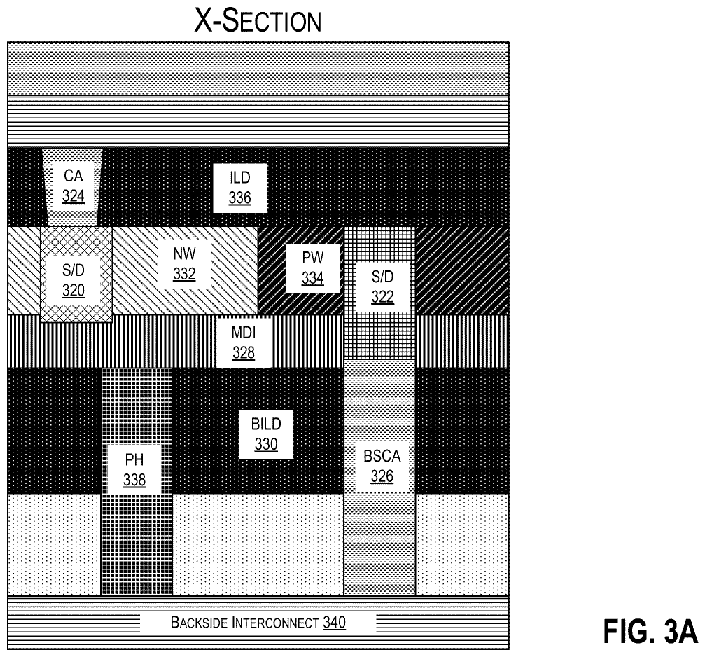

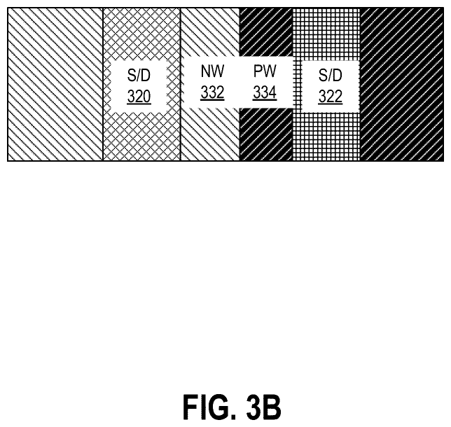

Reference now is made to FIGS. 3A-3B, which are simplified a cross-section view and a top view of a semiconductor device, respectively, consistent with illustrative embodiments. FIG. 3A illustrates a set of diodes, in accordance with some embodiments. The diodes can form a passive device region including multiple functional regions that provide electrical connectivity, isolation, and protection, enhancing the device's versatility and reliability.

In some embodiments, the semiconductor device includes a passive device region with a detailed structure designed for efficient charge control and robust operation. The device includes a first source/drain region, S/D 320, and a second source/drain region, S/D 322. The S/D regions are doped to create specific electrical properties, with the S/D 322 providing one terminal for charge flow and the S/D 322 serving as the complementary terminal. A frontside contact, CA 324, is directly connected to the S/D 322, allowing for electrical connections from the top surface, while a backside contact, BSCA 326, connects to the S/D 322, enabling electrical access from the bottom surface. The S/D regions are bonded and electrically integrated using a bonding oxide, MDI 328, which secures them to a backside interlayer dielectric, BILD 330.

In some embodiments, the MDI 328 ensures mechanical stability and electrical isolation while facilitating integration between the top and bottom regions. In some embodiments, the semiconductor device further includes a first doped region, NW 332, and a second doped region, PW 334, between the S/D 320 and the S/D 322. These doped regions provide a controlled transition between the source/drain regions, enhancing charge carrier movement and reduce (e.g. minimize) resistance. The ILD 336 overlays the PW 334 and NW 332 and the source/drain areas, ensuring electrical isolation and providing structural support. In some embodiments, the bottom surface of the S/D 322, which is in contact with the BSCA 326, lies below the top surface of the MDI 328, providing a structured arrangement that enhances electrical and structural alignment. The semiconductor device includes an N-well region, NW 334, and a P-well region, PW 334, which define the conduction and isolation areas of the device.

In some configurations, the S/D 322 extends at least partially into the MDI 328, which enhances integration and improves the electrical connectivity and mechanical stability of the device. The device can also feature configurations where the S/D 322 matches the doping type of the S/D 322, and the PW 334 matches the doping type of the S/D 320, creating complementary doping profiles. The semiconductor can include placeholder, PH 338, and a backside interconnect 340.

In some embodiments, the device forms an N+/NW/PW/P+ diode. Such a diode includes an N+ cathode, a P+ anode, and intermediate n-well and p-well regions. These regions establish the P-N junctions that define the diode's rectification and isolation capabilities. The integration of N+ and P+ layers, along with the n-well and p-well regions, enhances the diode's efficiency and robustness for applications such as electrostatic discharge (ESD) protection and signal rectification. The semiconductor device, with its integration of doped regions, bonding layers, source/drain regions, and contact configurations, offers a versatile and high-performance solution for advanced electronic applications.

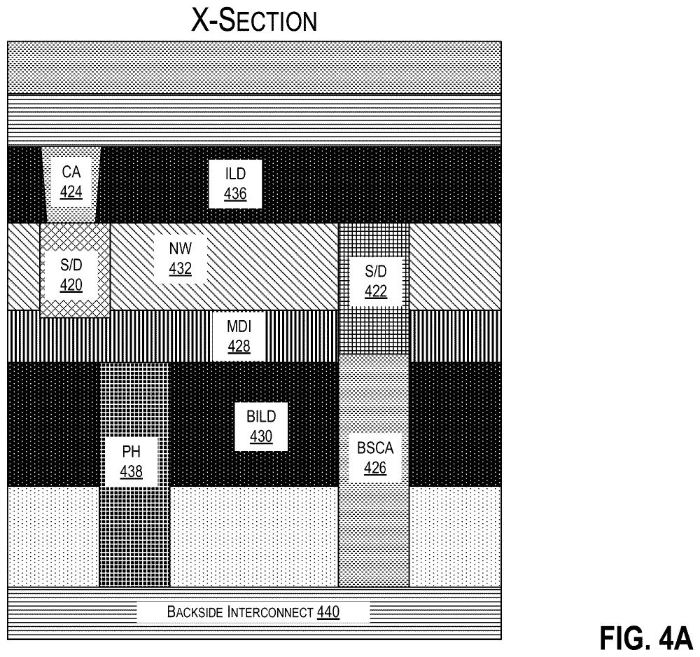

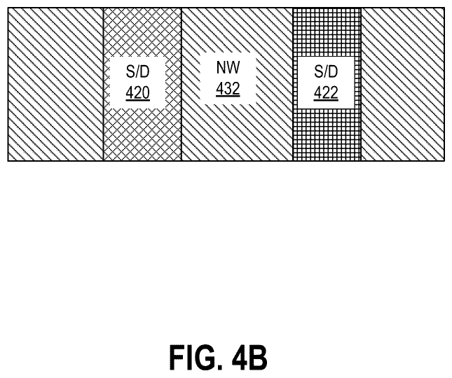

Reference now is made to FIGS. 4A-4B, which are simplified a cross-section view and a top view of a semiconductor device, respectively, consistent with illustrative embodiments. FIG. 4A illustrates a set of diodes, in accordance with some embodiments. In some embodiments, the semiconductor device integrates backside power, enabling efficient power distribution and management through the lower layers of the semiconductor. A structural feature of the device is an isolation layer, which separates a silicon top layer from a lower BILD 430. This separation provides electrical isolation, thermal management, and mechanical stability, enabling the integration of complex circuit components within a compact structure.

The semiconductor device includes an N-well region, NW 432, that defines regions with specific electrical characteristics, enabling precise control over charge carrier movement. The NW 432 creates a foundation for forming complementary components, such as diodes and transistors, within the stacked architecture. Additionally, the semiconductor device incorporates heavily doped N+ and P+ epitaxial (epi) layers, e.g., S/D 420 and the S/D 422, which enhance the electrical conductivity and current-carrying capabilities of the device. The S/D 420 and the S/D 422 reduce resistance and improve overall efficiency, making them essential for high-performance applications. The semiconductor device can include MDI 428, ILD 436, PH 438, and backside interconnect 440.

In some embodiments, the semiconductor device includes frontside contact, CA 424, and backside contact, BSCA 426, for the S/D 420 and the S/D 422, respectively. The CA 424 provides electrical access to the upper components of the semiconductor device, enabling integration with the frontside circuitry. The BSCA 426 establishes electrical pathways to the lower layers, such as the backside power distribution network, optimizing power delivery and reducing (e.g., minimizing) parasitic effects. Such a dual-contact configuration enhances the flexibility and scalability of the device, making it suitable for advanced circuit designs that require efficient integration of power and signal paths.

The semiconductor device forms an N+/NW/P+ diode within the stacked architecture. The diode consists of an N+ cathode, an n-well intermediate layer, and a P+ anode. This configuration establishes a P-N junction with excellent rectification and current-handling capabilities. The inclusion of the n-well provides isolation and defines the electrical behavior of the diode, while the N+ and P+ epi layers enhance the injection and collection of charge carriers, ensuring efficient operation.

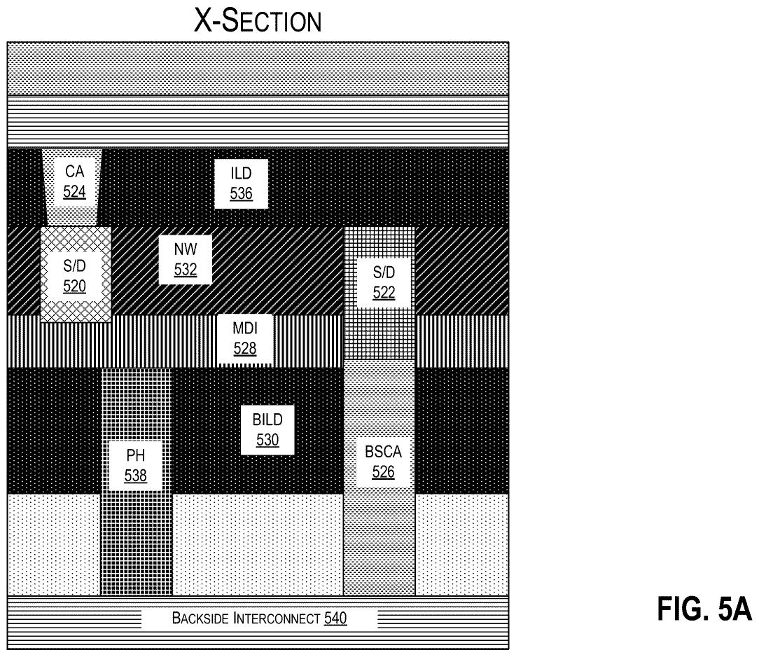

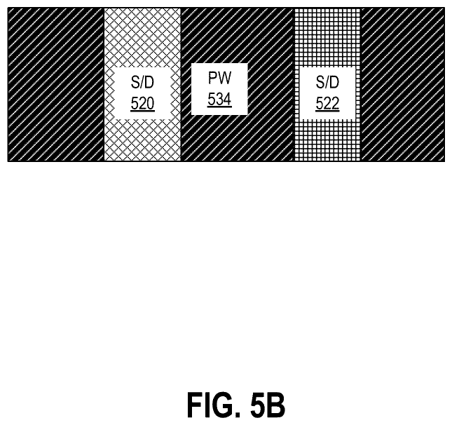

Reference now is made to FIGS. 5A-5B, which are simplified a cross-section view and a top view of a semiconductor device, respectively, consistent with illustrative embodiments. FIG. 5A illustrates a set of diodes, in accordance with some embodiments. In some embodiments, the semiconductor device incorporates a P-well, PW 534, that forms the foundation for its electrical behavior. The PW 534 is lightly doped with P-type impurities, creating a hole-rich environment that serves as a key component for defining the conduction and isolation properties of the device. The semiconductor device includes heavily doped N+ and P+ epitaxial layers, e.g., the S/D 520 and the S/D 522. The S/D 520 doped with a high concentration of N-type impurities, provides an electron-rich environment, facilitating efficient electron injection and conduction. The S/D 522 heavily doped with P-type impurities, enhances hole conduction and ensures a robust electrical connection for current flow. The epitaxial layers are positioned to work in conjunction with the PW 534, enabling control over charge carrier movement and improving the device's current-carrying capacity. The heavy doping in the S/D 520 and S/D 522 reduces resistance and enhances performance, particularly in high-current applications.

The semiconductor device includes a frontside contact, CA 524 and a backside contact, BSCA 526, for the S/D 520 and S/D 522, respectively. The CA 524 is positioned on the upper surface of the semiconductor, providing a direct electrical connection to the S/D 520 and S/D 522. These contacts allow the integration of the device with frontside circuitry, enabling signal and power routing. The BSCA 526 located on the lower surface of the device, establishes electrical pathways to the S/D 520 and S/D 522 from the bottom of the semiconductor. This dual-contact configuration ensures that the device can manage bidirectional current flow and integrate seamlessly with both frontside and backside circuit elements, optimizing flexibility and design scalability. The semiconductor device can include backside interconnect 540, BILD 530, PH 538, ILD 536, N-well 532, and MDI 528.

The semiconductor device includes an N+/PW/P+ diode formed within the top silicon layer. This diode consists of an N+ region acting as the cathode, a P-well region as the intermediate layer, and a P+ region serving as the anode. The N+/PW junction forms a rectifying P-N junction that controls current flow under forward or reverse bias conditions. The P+ region enhances hole injection into the P-well, while the N+ region facilitates efficient electron collection, ensuring that the diode operates with low forward voltage drop and high current-carrying efficiency. The inclusion of the P-well provides isolation and defines the electrical behavior of the diode, while the heavily doped N+ and P+ layers ensure strong and reliable conduction.

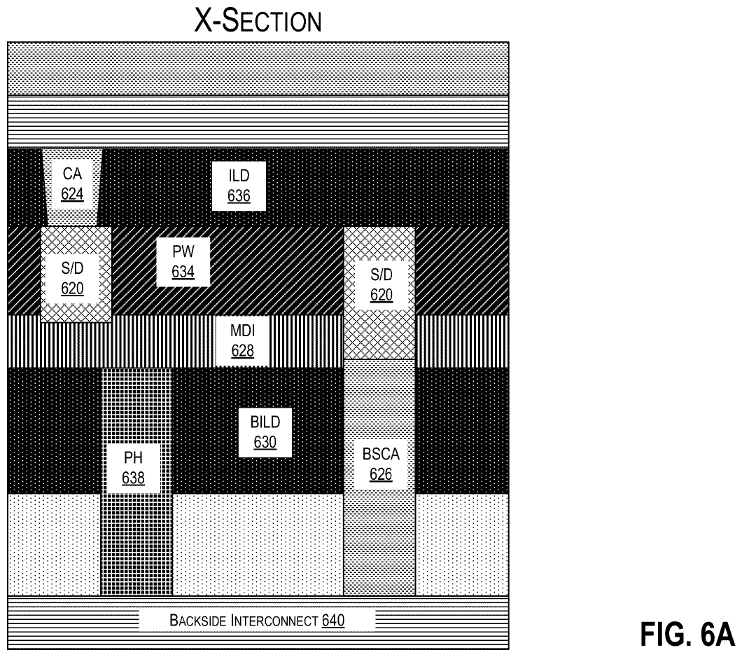

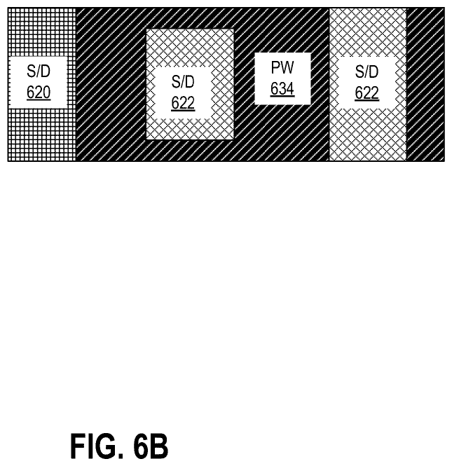

Reference now is made to FIGS. 6A-6B, which are simplified a cross-section view and a top view of a semiconductor device, respectively, consistent with illustrative embodiments. FIG. 6A illustrates a set of diodes, in accordance with some embodiments. In some embodiments, the semiconductor device incorporates a P-well, PW 634, which serves as a foundational region for defining the electrical behavior of the device. The PW 634 is lightly doped with P-type impurities, creating a hole-rich region that acts as an active zone for charge modulation and isolation. The semiconductor device integrates heavily doped N+ epitaxial layers, e.g., S/D 620 and S/D 622. The S/D 620 and S/D 622 are doped with a high concentration of N-type impurities, creating an electron-rich environment that facilitates efficient electron conduction.

The semiconductor device features a frontside contact, CA 624 and a backside contact, BSCA 626, for the S/D 620 and S/D 622, respectively. The CA 624 is positioned on the upper surface of the silicon layer, providing direct electrical access to the S/D 620 and S/D 622 for integration with frontside circuitry. These contacts enable efficient signal routing and power distribution. BSCA 626 located on the lower surface, offers similar connectivity for the S/D 620 and S/D 622 providing a pathway for current flow to the backside circuitry or power distribution network. This dual-contact configuration allows for flexible circuit integration and bidirectional current handling, making the device suitable for complex designs. The semiconductor device can include backside interconnect 640, BILD 630, PH 638, ILD 636, and MDI 628.

The semiconductor device further includes an N+/PW/N+ lateral NPN structure formed within the top silicon layer. The lateral NPN configuration features two N+ regions separated by a P-well region, which acts as the base of the transistor. The N+ regions function as the emitter and collector, while the P-well base modulates the flow of electrons between them. The N+/PW junctions form the essential P-N interfaces that enable the bipolar action of the transistor. Depending on the design requirements, the P-well base can either be floating or electrically contacted. A floating P-well provides isolation and reduces (e.g., minimizes) interactions with other components, while a contacted P-well allows for active modulation of the NPN transistor's behavior, offering greater control over its operation.

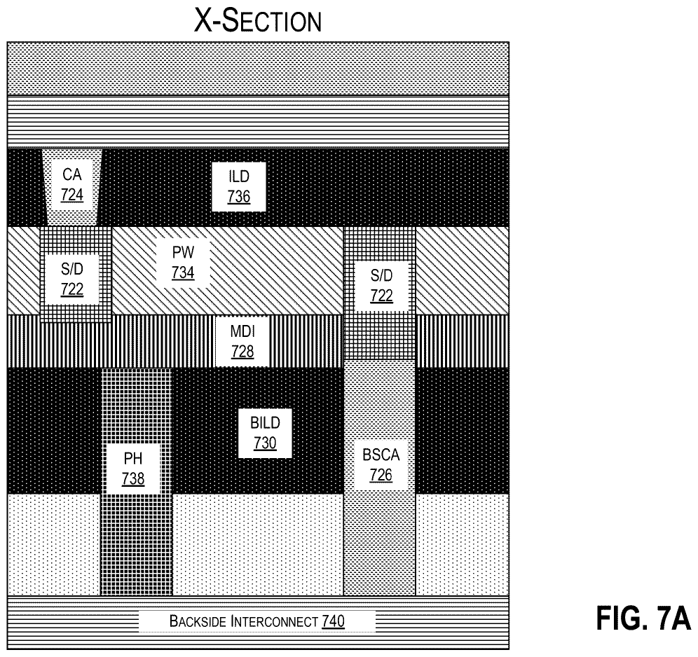

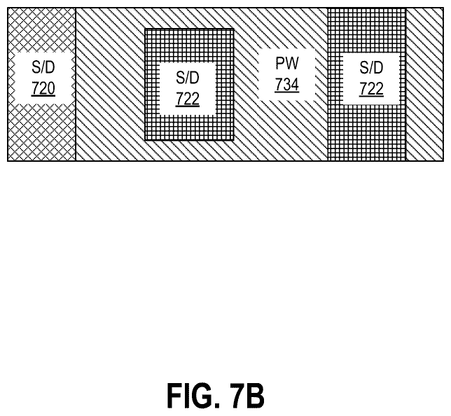

Reference now is made to FIGS. 7A-7B, which are simplified a cross-section view and a top view of a semiconductor device, respectively, consistent with illustrative embodiments. In some embodiments, the semiconductor device incorporates an N-well, NW 732, which serves as a foundational region for defining the electrical behavior of the device. The NW 732 is lightly doped with N-type impurities. The semiconductor device integrates heavily doped P+ epitaxial layers, e.g., S/D 720 and S/D 722. The S/D 720 and S/D 722 are doped with a high concentration of P-type impurities, creating an electron-rich environment that facilitates efficient electron conduction. The semiconductor device can include backside interconnect 740, BILD 730, PH 738, ILD 736, P-well 734, and MDI 728.

The semiconductor device features a frontside contact, CA 724 and a backside contact, BSCA 726, for the S/D 720 and S/D 722, respectively. The CA 724 is positioned on the upper surface of the silicon layer, providing direct electrical access to the S/D 720 and S/D 722 for integration with frontside circuitry. These contacts enable efficient signal routing and power distribution. BSCA 726 located on the lower surface, offers similar connectivity for the S/D 720 and S/D 722 providing a pathway for current flow to the backside circuitry or power distribution network. This dual-contact configuration allows for flexible circuit integration and bidirectional current handling, making the device suitable for complex designs.

In some embodiments, the semiconductor device incorporates a P+/NW/P+ lateral PNP structure formed within the silicon layer. This structure includes two heavily doped P+ regions separated by an n-well (NW), which acts as the base of the transistor. The P+ regions function as the emitter and collector, while the NW serves as the control region that modulates the flow of charge carriers between the emitter and collector. The P+/NW/P+ configuration is a component of a lateral PNP transistor, allowing for precise control over current flow in a planar semiconductor design.

The P+ emitter is designed to inject holes (positive charge carriers) into the NW base region when a forward bias is applied across the base-emitter junction. The NW base is lightly doped with N-type impurities, creating an electron-rich environment that facilitates the recombination of holes injected from the emitter. The remaining holes diffuse across the NW base and are collected by the P+ collector, forming the primary current path of the transistor. This lateral flow of holes from the emitter to the collector through the NW base defines the operation of the PNP transistor, making it suitable for amplifying or switching applications.

The NW base region can be configured as either floating or contacted, depending on the application requirements. A floating NW base is electrically isolated from other components, allowing the PNP transistor to operate without direct external control over the base region. This configuration is useful for scenarios where reduced (e.g., minimal) interference or self-regulated operation is desired, such as in specific analog circuits or passive structures. Conversely, a contacted NW base includes an electrical connection to an external control circuit, enabling active modulation of the base potential. This allows for control over the transistor's operation, including precise adjustments to the current flow and switching behavior.

The P+/NW/P+ lateral PNP structure benefits from its planar design, which ensures compatibility with standard CMOS processes and enables integration with other circuit elements. The lateral configuration allows the current to flow parallel to the surface of the silicon layer, making it efficient for applications requiring compact layouts and low parasitic effects. The use of heavily doped P+ regions ensures robust hole injection and collection, while the NW base provides sufficient isolation and control over charge carrier movement. This P+/NW/P+ lateral PNP configuration is suitable for a variety of applications, including analog signal processing, voltage level shifting, and current amplification. Its flexibility in operation, with the option for either a floating or contacted NW base, adds versatility, making it adaptable to a wide range of circuit designs.

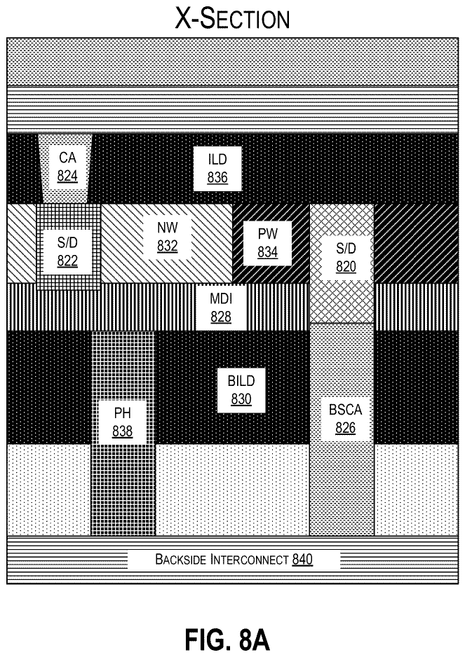

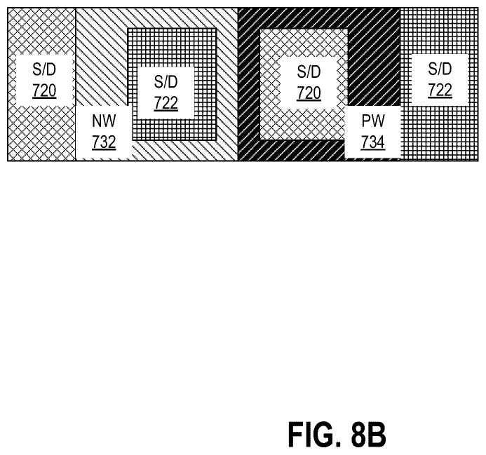

Reference now is made to FIGS. 8A-8B, which are simplified a cross-section view and a top view of a semiconductor device, respectively, consistent with illustrative embodiments. In some embodiments, the semiconductor device includes an n-well, NW 832, and a p-well, PW 834. These layers serve as the foundation for precise electrical behavior, enabling controlled charge carrier flow and defining isolation regions within the semiconductor. The n-well introduces electron-rich regions (N-type), while the p-well introduces hole-rich regions (P-type). Together, these layers create the framework for forming various semiconductor junctions and device architectures. The semiconductor device can include backside interconnect 840, BILD 830, PH 838, ILD 836, and MDI 828.

Heavily doped N+ and P+ epitaxial layers, S/D 820 and S/D 822, are integrated into the silicon top layer. The S/D 822, doped with a high concentration of N-type impurities, ensures efficient electron injection and conduction, reducing (e.g., minimizing) resistance and enhancing performance. Similarly, the S/D 820, with a high concentration of P-type impurities, facilitates strong hole conduction, ensuring robust electrical connectivity. The S/D 820 and S/D 822 improve the current-carrying capacity and reliability of the device, especially in high-performance and high-current applications.

The device features frontside, CA 824, and backside contact, BSCA 826, for the S/D 822 and S/D 820, respectively. The CA 824 is positioned on the upper surface of the device, providing direct electrical access to the S/D 822 for integration with the frontside circuitry. The BSCA 826, located on the lower surface, establishes electrical pathways to the S/D 820 from the backside of the semiconductor. This dual-contact configuration ensures seamless integration with both the frontside and backside circuit elements, supporting bidirectional current flow and optimized power distribution.

In some embodiments, the S/D 820 is structured with n-well (NW) channels positioned above and below it. The NW channels create electron-rich regions that interact with the S/D 820, providing electrical isolation and enabling controlled modulation of charge carriers. The arrangement enhances the device's performance by creating well-defined conduction paths and reducing parasitic interactions. Similarly, the S/D 822 is surrounded by p-well (PW) channels above and below it, introducing hole-rich regions that improve isolation and charge control. The p-well channels ensure management of electron flow in the S/D 822, enhancing the overall efficiency and stability of the device.

The semiconductor device also includes a lateral PNPN structure formed within the top silicon layer, consisting of a P+/NW/PW/N+ configuration. The lateral PNPN structure creates a silicon-controlled rectifier (SCR) that combines P-N junctions in a series arrangement. The P+ region serves as the anode, while the N+ region acts as the cathode. The intermediate n-well and p-well regions form the base regions of the SCR, modulating the flow of charge carriers between the anode and cathode. When a trigger voltage is applied, the SCR transitions from a high-impedance state to a low-impedance state, allowing it to conduct large currents efficiently. The lateral PNPN structure benefits from its planar configuration, which aligns the current flow parallel to the surface of the silicon layer. Such a design is compatible with standard CMOS processes and enables compact, high-density integration with other circuit elements. The inclusion of n-well and p-well channels surrounding the P+ and N+ epitaxial layers further enhances the device's isolation and control, ensuring reliable operation under varying electrical conditions.

### Example Fabrication of A Passive Semiconductor Device in Shifted Stacked Transistors Structure

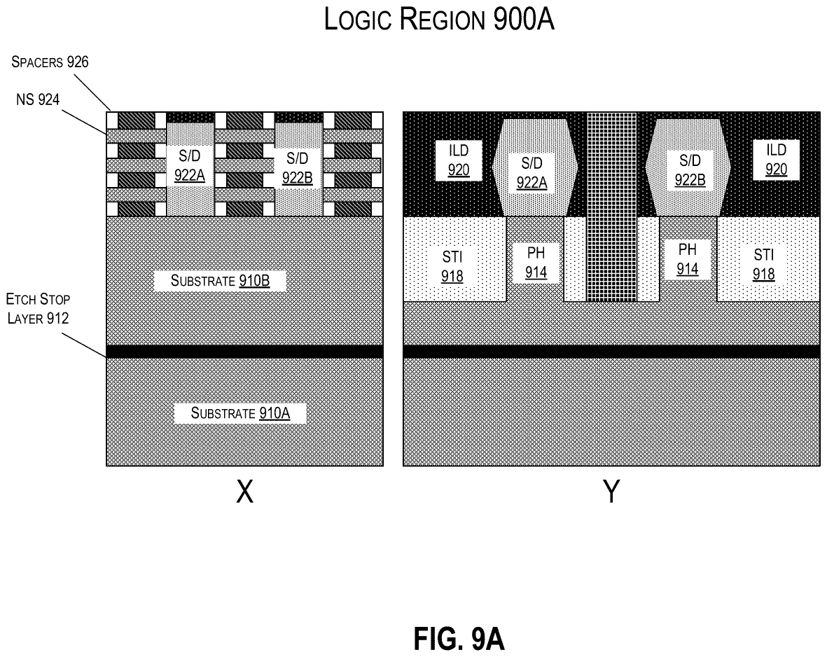

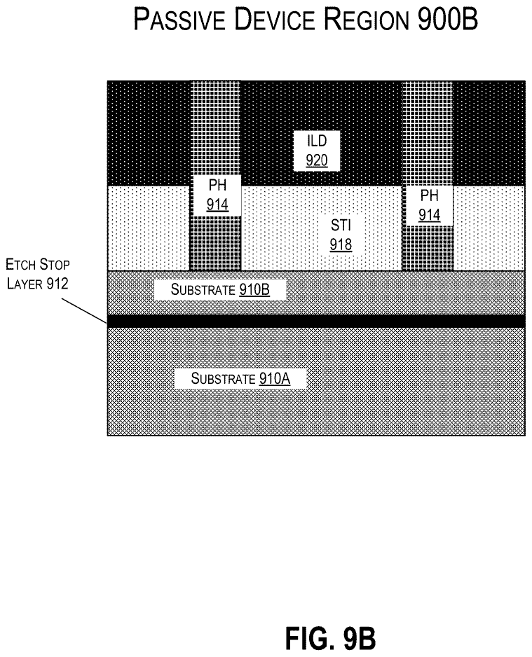

With the foregoing description of an example semiconductor device, it may be helpful to discuss an example process of manufacturing the same. To that end, FIGS. 9-23 illustrate various acts in the manufacture of a semiconductor device, consistent with illustrative embodiments.

Reference now is made to FIGS. 9A-9B, which are simplified cross-section views of a semiconductor device, after the preparation of the bottom layer, consistent with an illustrative embodiment. Figures denoted by A delict a logic region section of the semiconductor device, and figures denoted by B depict the passive device region section of the semiconductor device. The semiconductor can include a first substrate 910A, an etch stop layer 912, a second substrate 910B, sacrificial placeholders, PH 914, shallow trench isolation, ST 918, ILD 920, S/D 922A, S/D 922B, nanosheet gates, NS 924, and spacers 926. FIG. 9A depicts the logic region 900A and FIG. 9B depicts the passive device region 900B.

In the illustrative example depicted in FIGS. 9A-9B, the semiconductor device is depicted as being on silicon as the first substrate 910A and the second substrate 910B, while it will be understood that other types as the first substrate 910A and the second substrate 910B can be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the first substrate 910A and the second substrate 910B can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, the etch stop layer 912 is formed between the first substrate 910A and the second substrate 910B. The etch stop layer 912 can be a thin layer of material incorporated into the structure of the semiconductor device to provide a selective barrier against etching processes, preventing further removal of underlying materials during fabrication. The etch stop layer 912 can enable precise control over the etching depth and help define the desired device dimensions. The etch stop layer 912 can further provide a stopping point for the etching process, ensuring that specific layers or regions are not etched beyond a certain point, leading to accurate patterning and control of critical features. The etch stop layer 912 can create a distinct separation between different layers or components within the device structure, and prevent the undesired etching of underlying layers or materials, enabling the creation of complex, multi-layered structures with well-defined interfaces and boundaries. In some embodiments, the etch stop layer 912 acts as a protective barrier for sensitive or delicate materials to shield such materials from aggressive etchants, preventing damage or degradation during subsequent fabrication steps.

In some embodiments, prior to forming the etch stop layer 912, the first substrate 910A and/or the second substrate 910B is prepared by cleaning and removing any impurities or oxide layers. The etch stop layer 912 is deposited onto the first substrate 910A using techniques such as chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 912 can then be selectively etched, stopping at a predetermined depth, while protecting the underlying layers. After the etching process, the remaining photoresist can be removed through stripping techniques. While in some embodiments, SiGe is used to form the etch stop layer 912, in some embodiments, silicon nitride (SiN), silicon oxide (SiO2), or silicon oxynitride (SiON) can be used as the etch stop layer 912.

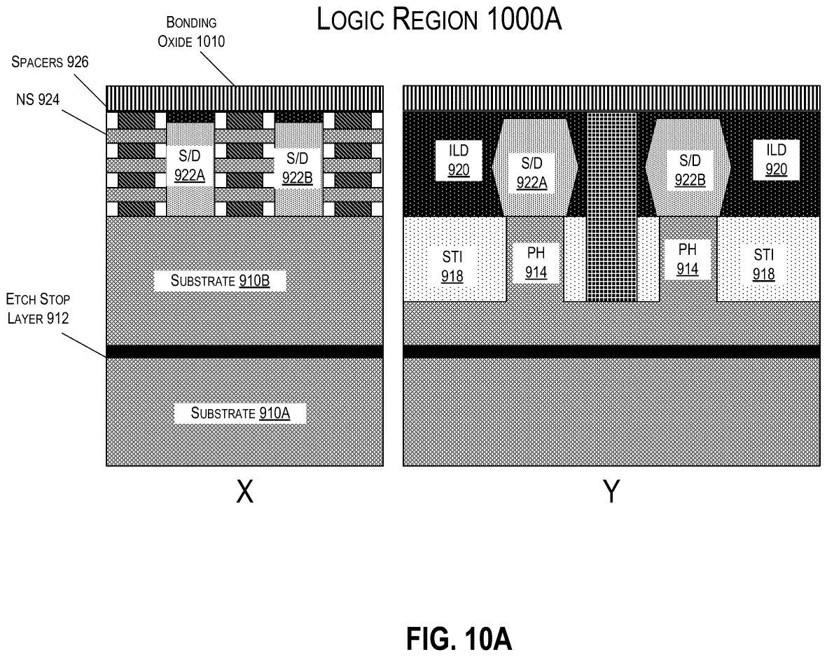

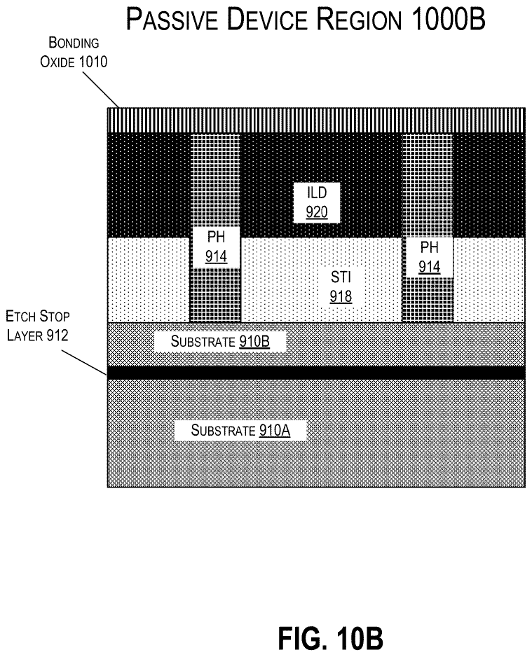

FIGS. 10A-10B illustrate the semiconductor device after the formation of the bonding oxide, in accordance with some embodiments. In some embodiments, the bonding oxide 1010 is formed over the semiconductor device on the logic region 1000A and the passive device region 1000B.

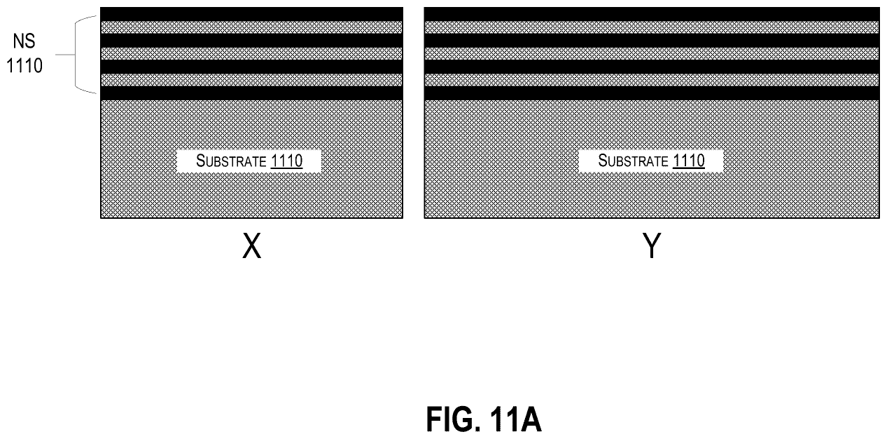

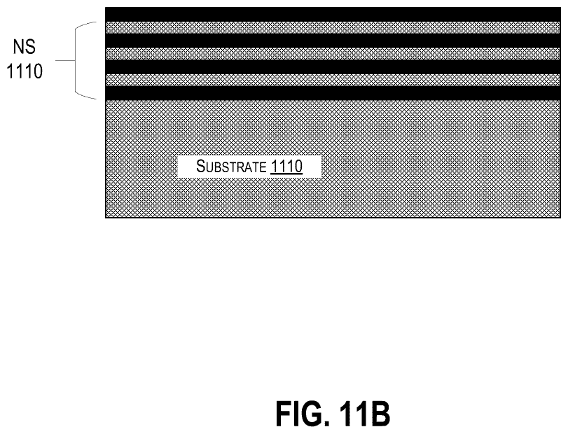

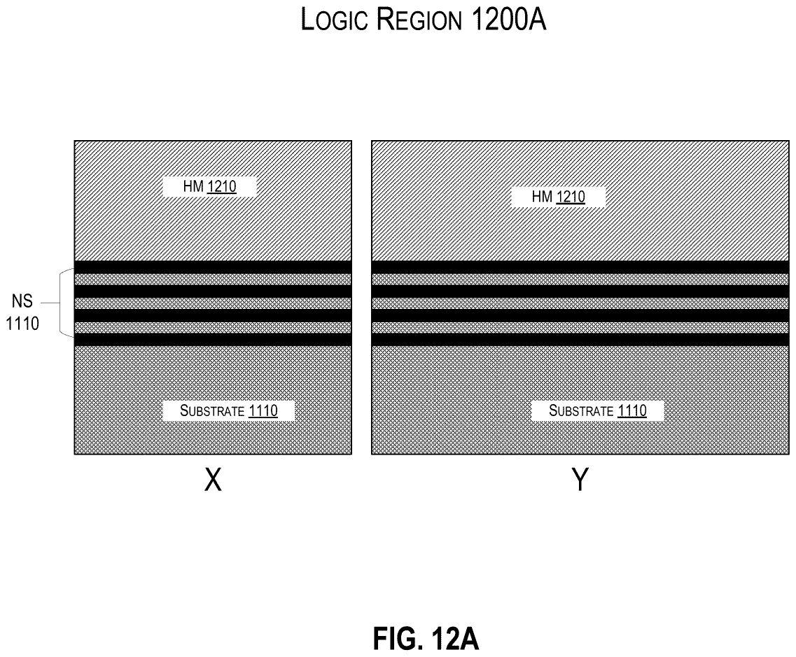

FIGS. 11A-11B illustrate the semiconductor device after the formation of the nanosheet gates in the top device layer, in accordance with some embodiments. In some embodiments, the nanosheet gates, NS 1110, are formed over the substrate. The NS 1110 can include alternating layers of Si and SiGe.

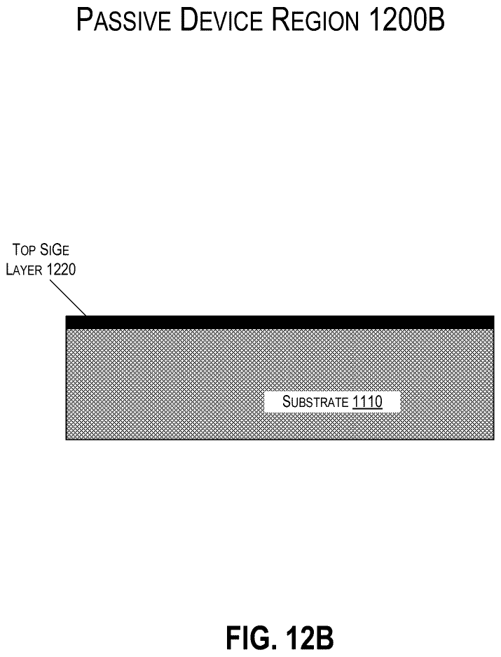

FIGS. 12A-12B illustrate the semiconductor device after the removal of the top layers, in accordance with some embodiments. In some embodiments, a hard mask, HM 1210, is formed over the logic region 1200A and the top layers of the NS are removed from the passive device region 1200B to expose the top SiGe layer 1220.

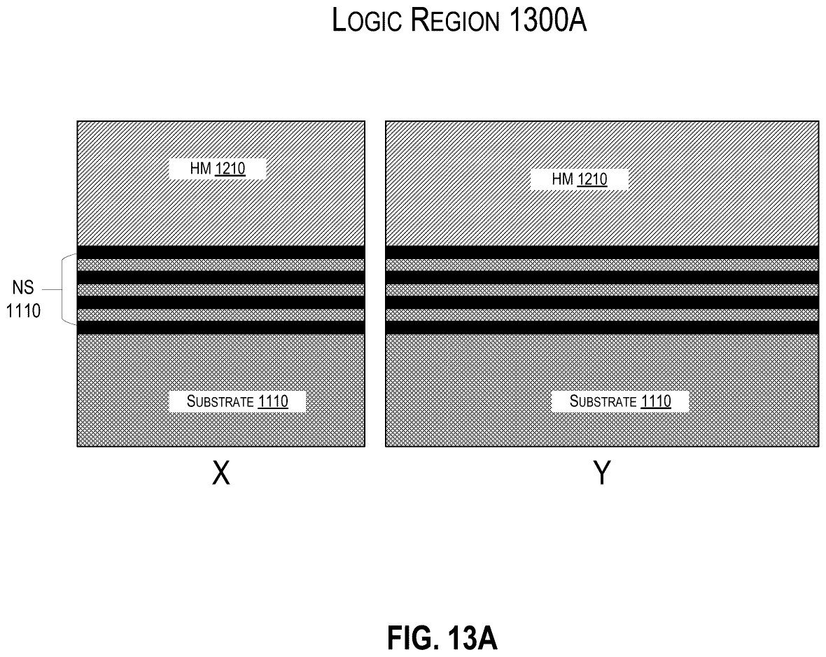

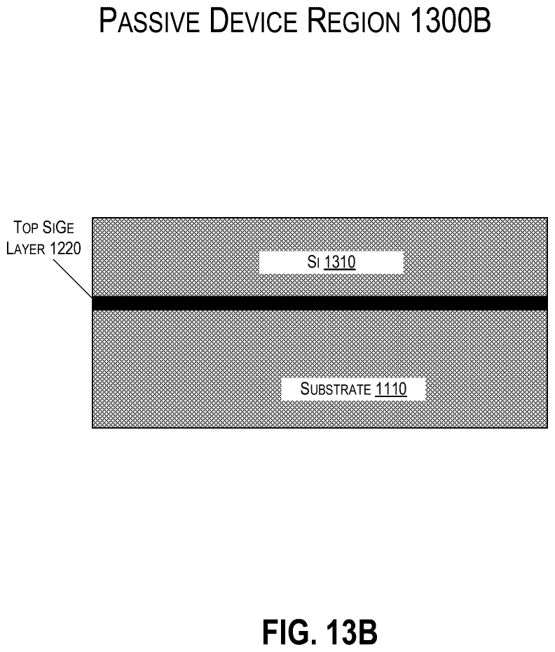

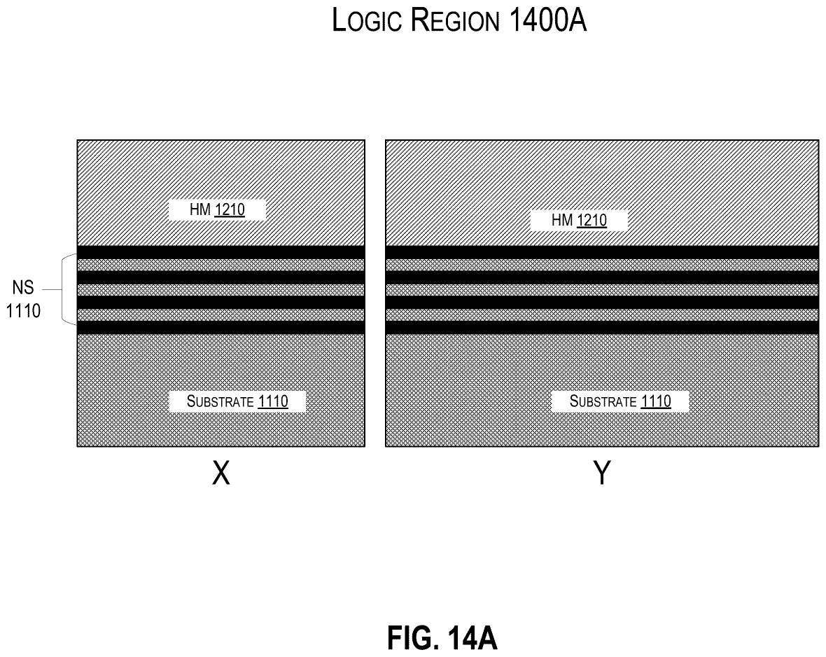

FIGS. 13A-13B illustrate the semiconductor device after the formation of a silicon layer, in accordance with some embodiments. In some embodiments, a silicon layer, Si 1310, is formed over the passive device region 1300B, while the logic region 1300A is protected by the HM 1210.

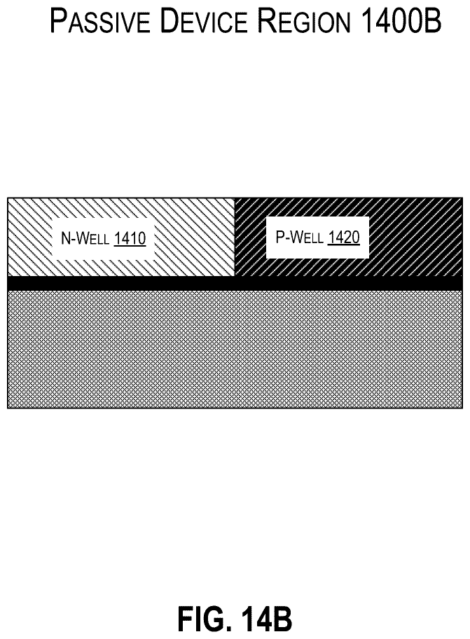

FIGS. 14A-14B illustrate the semiconductor device after the implantation of the silicon layer, in accordance with some embodiments. In some embodiments, the silicon layer is doped with proper implant to form an N-well 1410 and a P-well 1420 over the passive device region 1400B, while the logic region 1400A is protected by the HM 1210. As a result of the implantation, annealing the P-well 1420 and the N-well 1410 does not impact the bottom device layer.

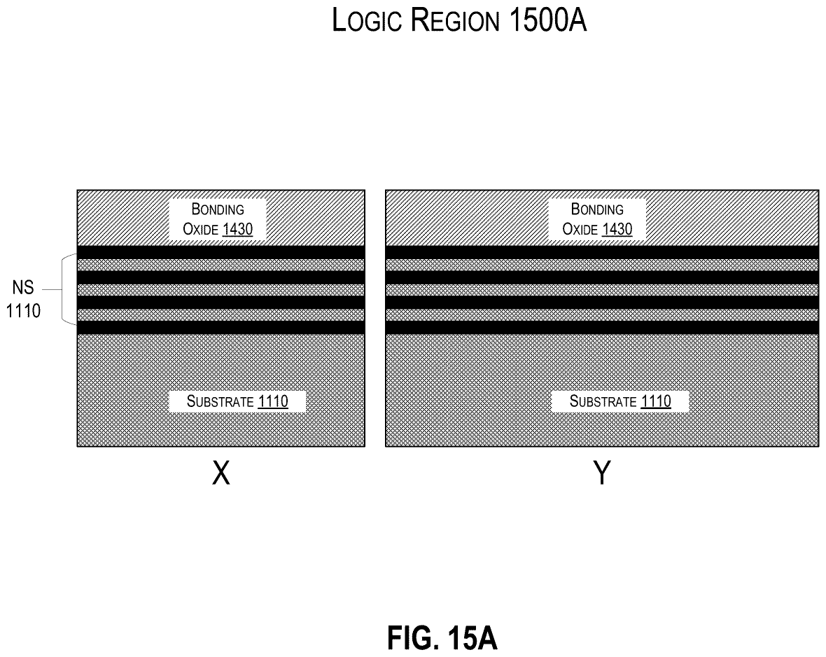

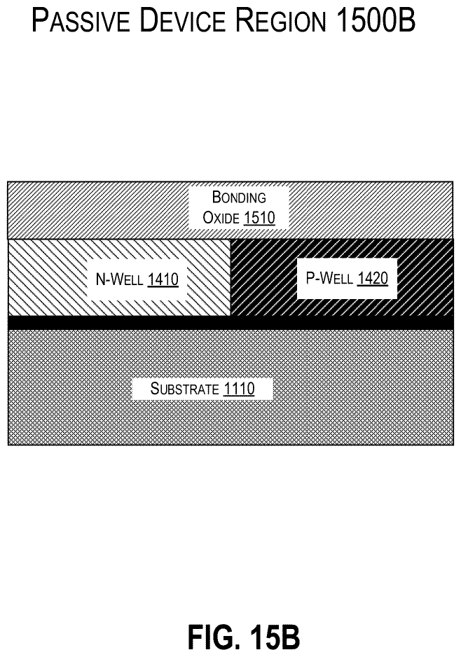

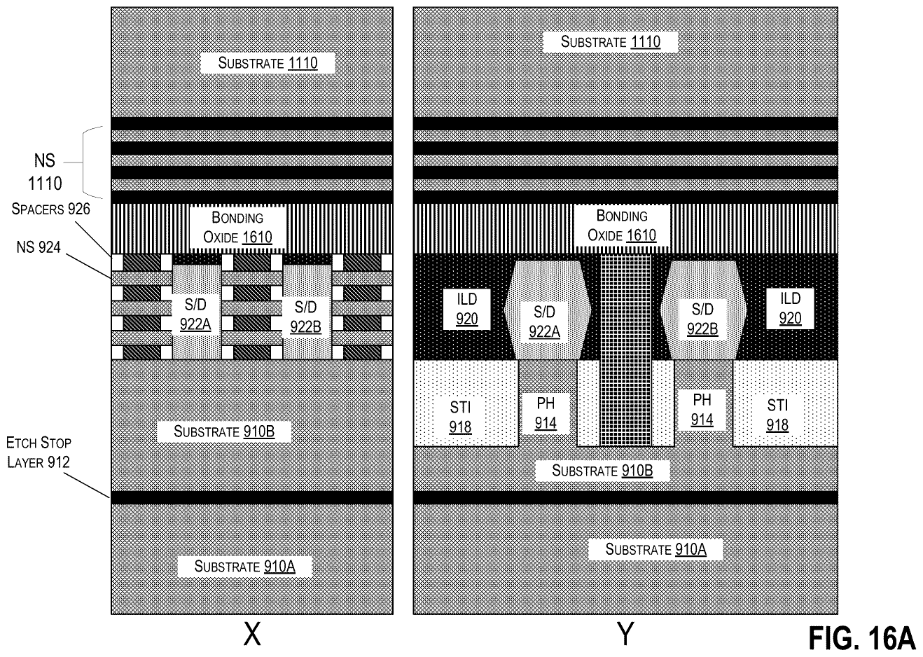

FIGS. 15A-15B illustrate the semiconductor device after the removal of the hard mask, in accordance with some embodiments. In some embodiments, the hard mask is removed from the logic region 1500A and a bonding oxide 1510 is formed over the logic region 1500A and the passive device region 1500B. Bonding oxide 1430 is formed over the semiconductor device.

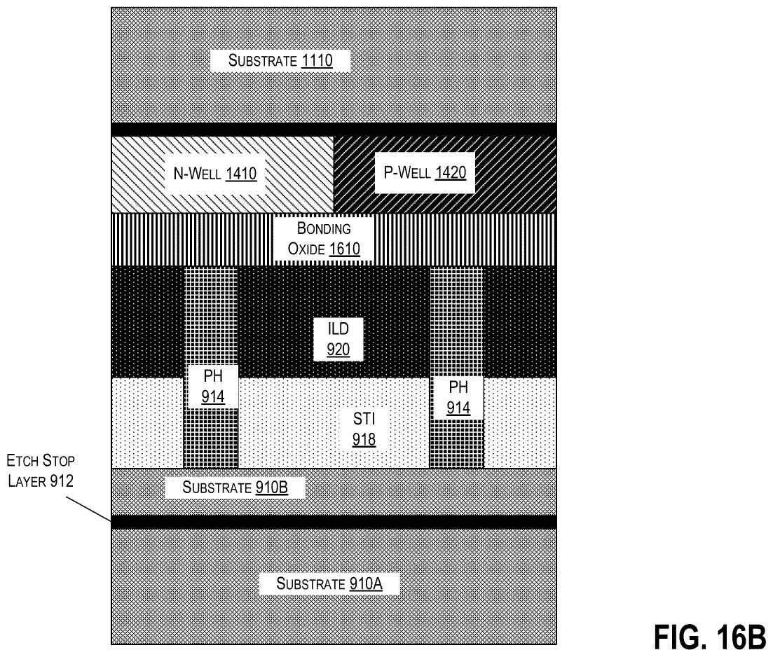

FIGS. 16A-16B illustrate the semiconductor device after the bonding the top device layer and the bottom device layer, in accordance with some embodiments. In some embodiments, the top device layer is bonded to the bottom device layer. The bonding oxides can form a bonding oxide 1610 between the top device layer and the bottom device layer.

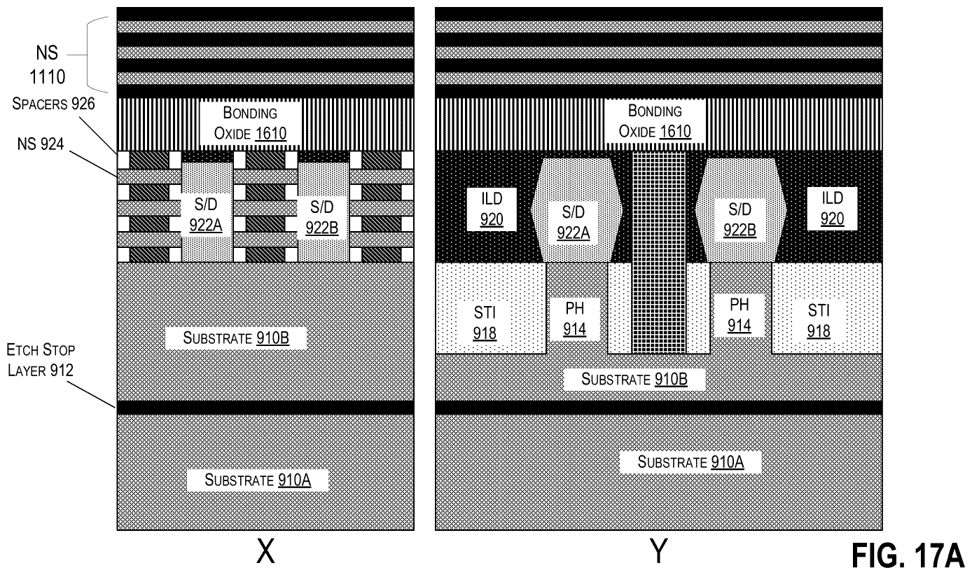

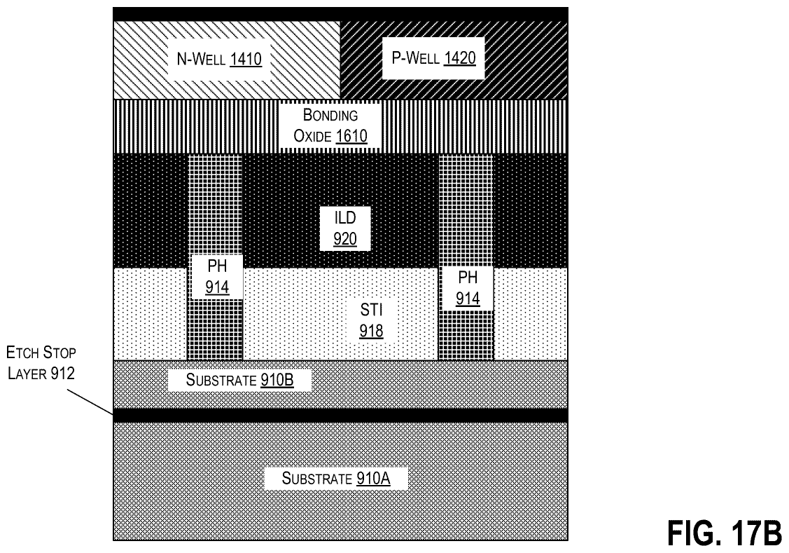

FIGS. 17A-17B illustrate the semiconductor device after the removal of the substrate, in accordance with some embodiments. In some embodiments, the substrate is removed from over the semiconductor device.

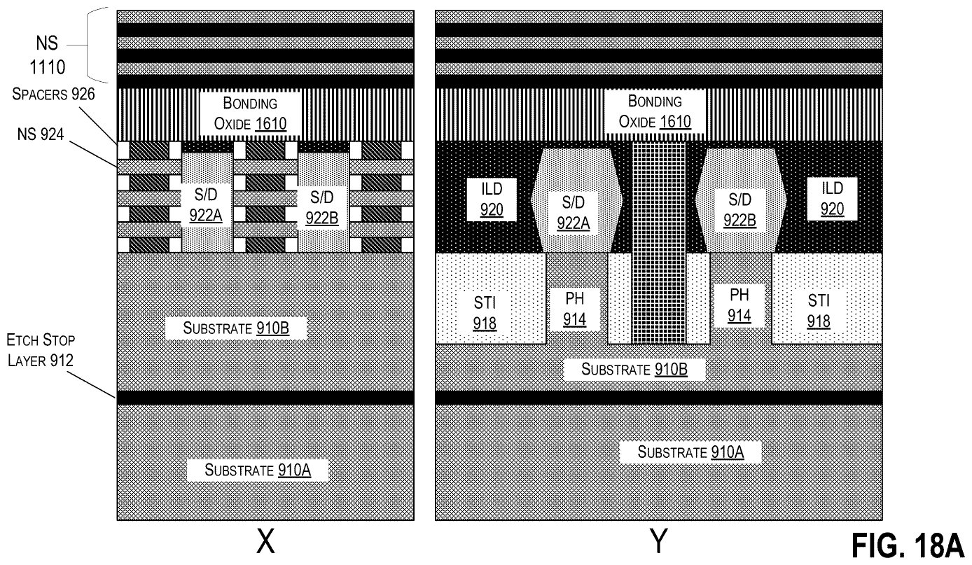

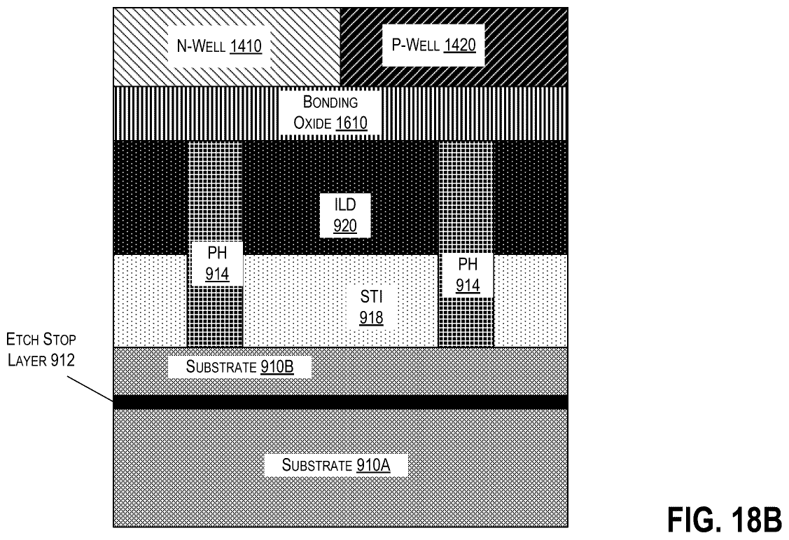

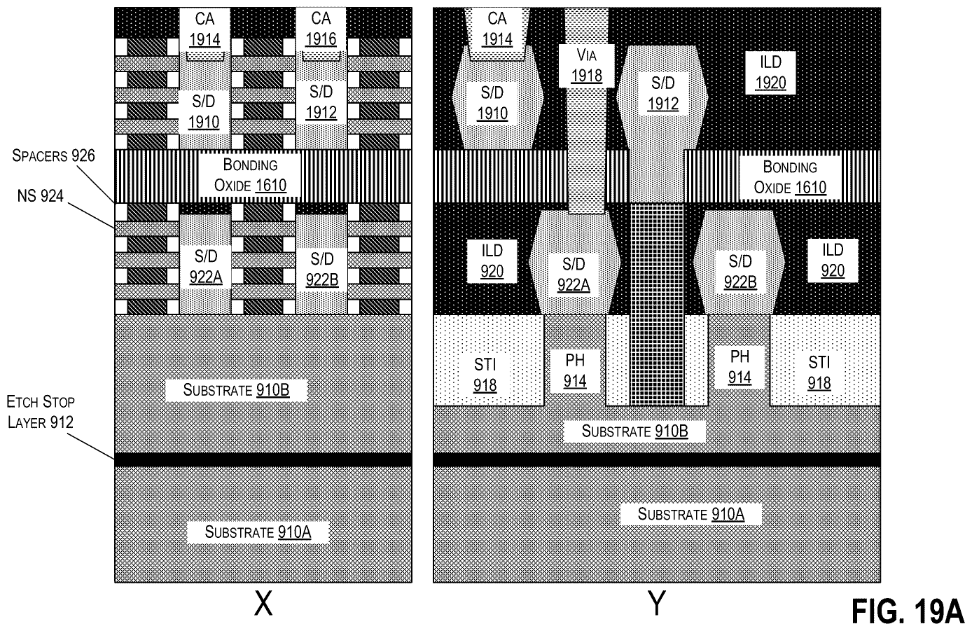

FIGS. 18A-18B illustrate the semiconductor device after the removal of the top SiGe layer, in accordance with some embodiments. In some embodiments, the uppermost SiGe layer is removed.

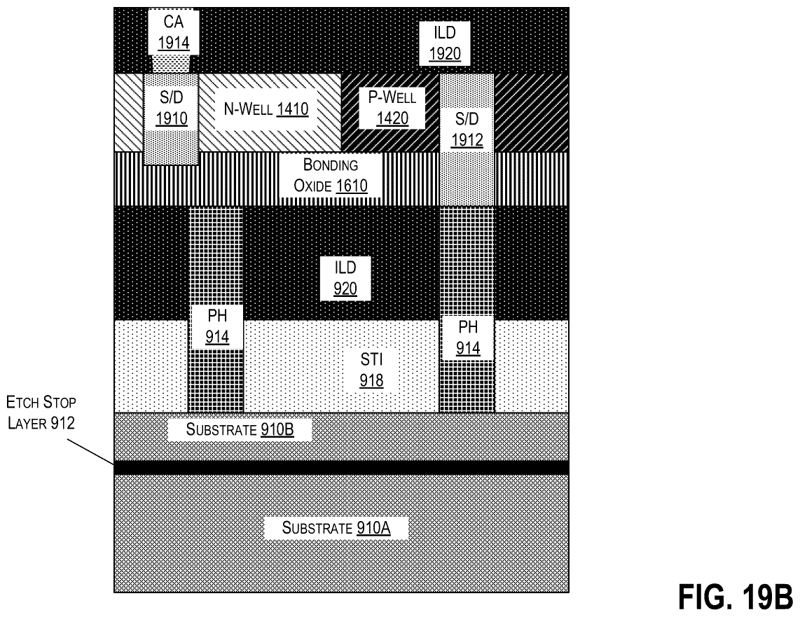

FIGS. 19A-19B illustrate the semiconductor device after the formation of the top device, in accordance with some embodiments. In some embodiments, the source/drain regions, S/D 1910, S/D 1912, frontside contacts, CA 1914 and CA 1916, a via 1918, and an ILD 1920 are formed.

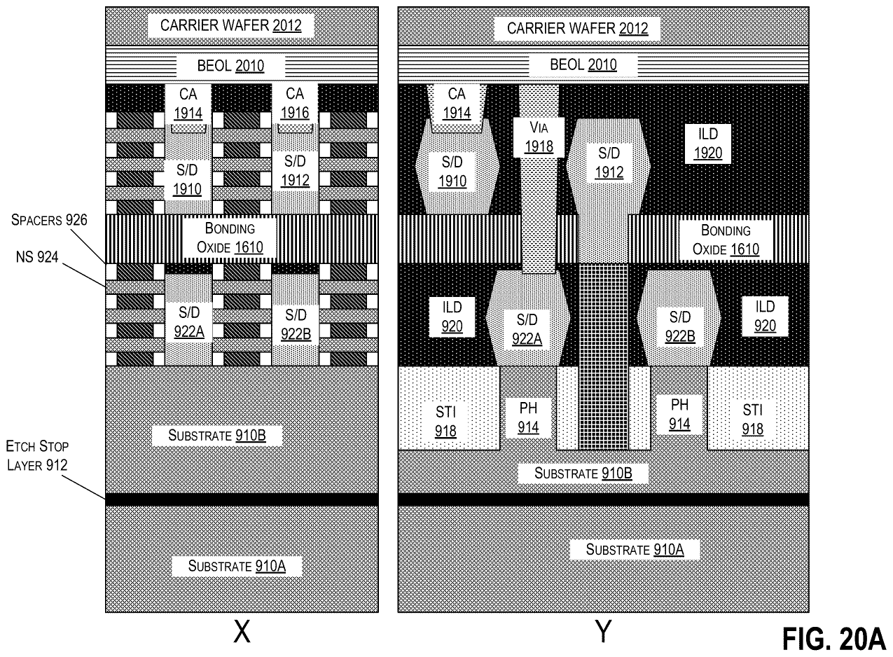

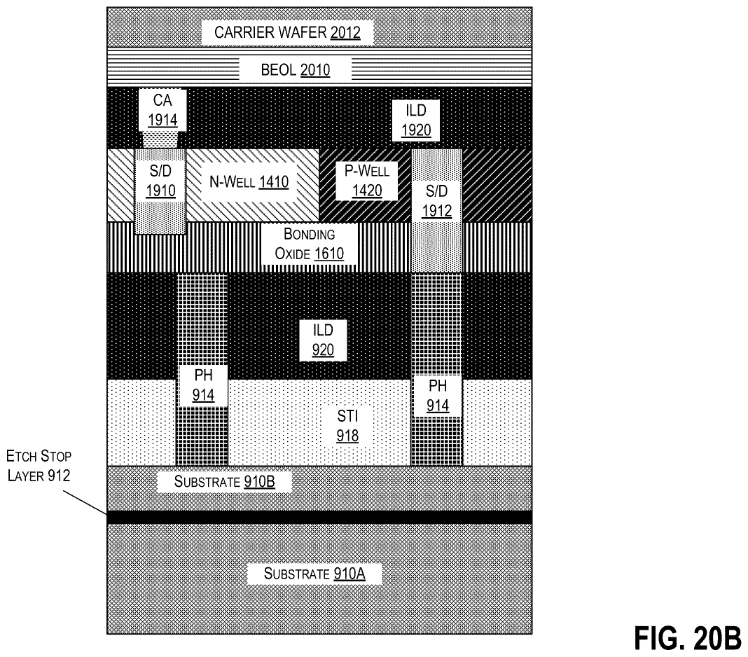

FIGS. 20A-20B illustrate the semiconductor device after the formation of the frontside interconnect, in accordance with some embodiments. In some embodiments, a back end of line, BEOL 2010, is formed over the semiconductor device. The BEOL 2010 includes wiring and interconnects to connect the frontside of the semiconductor device to other devices.

In various embodiments, carrier wafer bonding, also known as wafer-to-wafer bonding or chip-to-wafer bonding, is performed to join two semiconductor devices together by creating a permanent bond between them, e.g., via a carrier wafer 2012. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices. The metal layer can be deposited or transferred onto one or both semiconductor device surfaces, and the semiconductor devices can then be brought into contact and subjected to temperature and pressure to create a metallic bond.

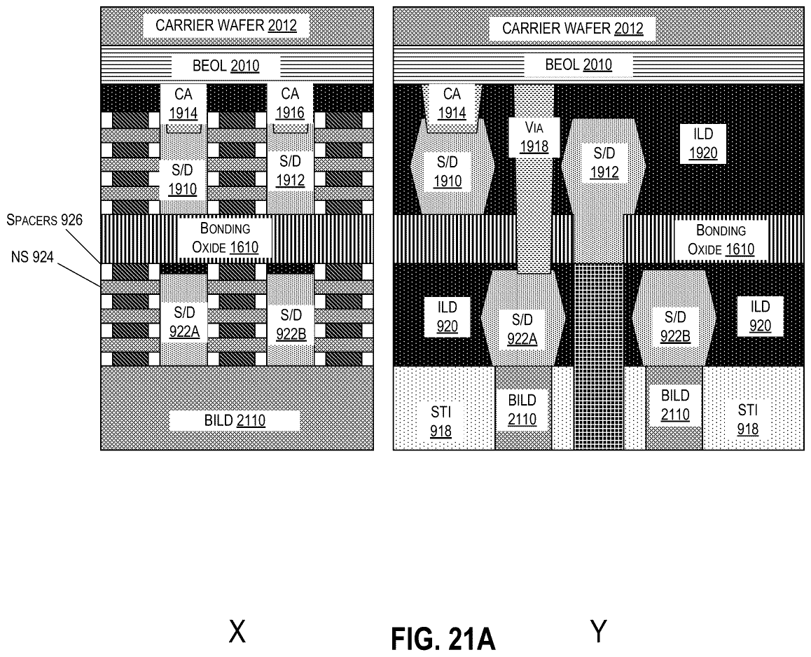

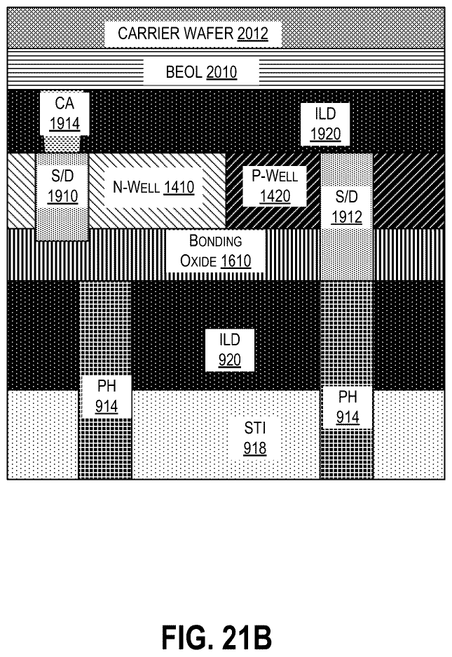

FIGS. 21A-21B illustrate the semiconductor device after the removal of the substrate, in accordance with some embodiments. In some embodiments, the first substrate, the etch stop layer and the second substrate are removed and a backside ILD, BILD 2110, is formed below the semiconductor device.

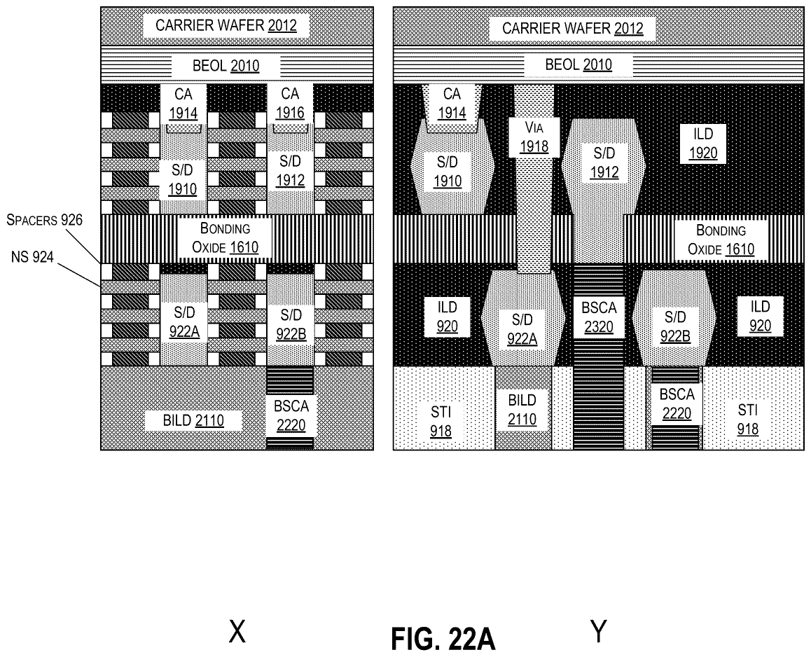

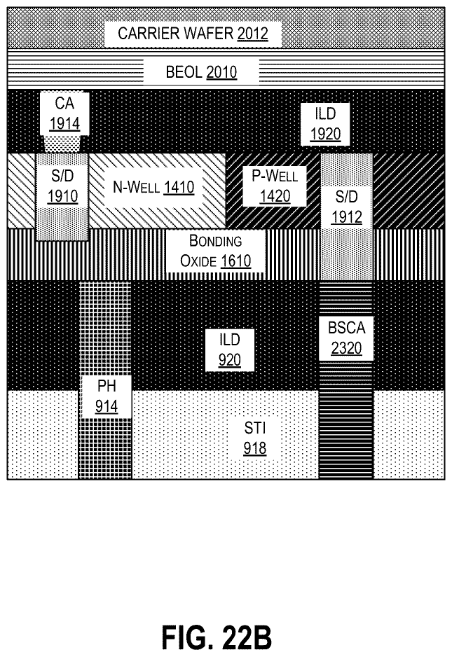

FIGS. 22A-22B illustrate the semiconductor device after the removal of the placeholders, in accordance with some embodiments. In some embodiments, some of the placeholders are selectively removed from the backside of the semiconductor device. Backside contacts, BSCA 2220 and BSCA 2320, can be formed.

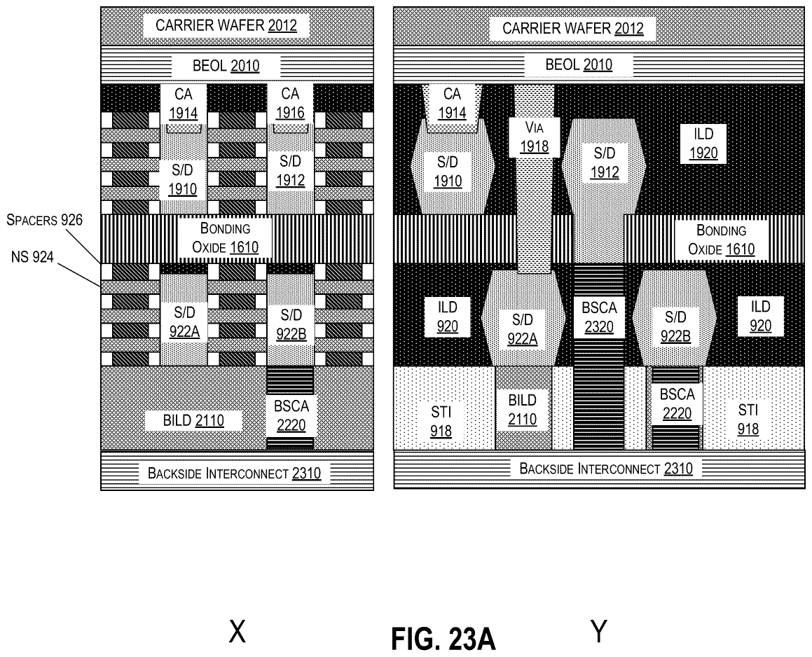

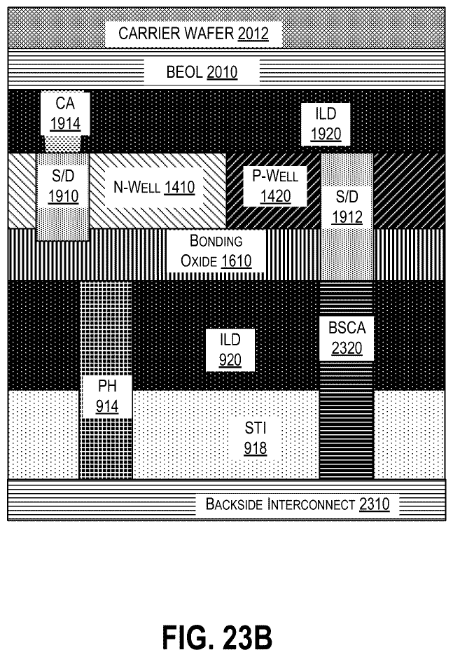

FIGS. 23A-23B illustrate the semiconductor device after the formation of the backside interconnect, in accordance with some embodiments. In some embodiments, the backside interconnect 2310 is formed below the semiconductor device.

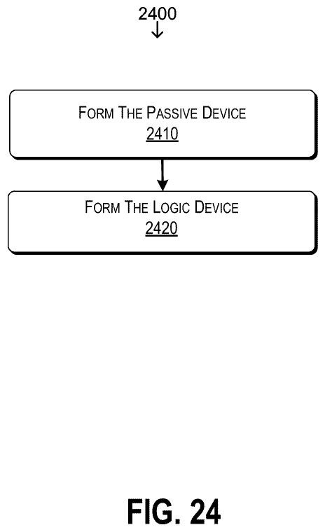

FIG. 24 illustrates a block diagram of a method 2400 for forming the semiconductor device, in accordance with some embodiments. As shown by block 2410, a passive device region is formed. The passive device region includes a first source/drain region, a second source/drain region, a frontside contact over the first source/drain region, a backside contact below the second source/drain region, and a bonding oxide bonding the first source/drain region and the second source/drain region to a backside interlayer dielectric.

As shown by block 2420, a logic region is formed. The logic region includes a top transistor, a bottom transistor and a bonding oxide separating the top transistor and the bottom transistor.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a passive device region comprising:
a first source/drain region;
a second source/drain region;
a frontside contact over the first source/drain region;
a backside contact below the second source/drain region; and
a bonding oxide bonding the first source/drain region and the second source/drain region to a backside interlayer dielectric.

2. The semiconductor device of claim 1, further comprising:
a first doped region and a second doped region between the first source/drain region and the second source/drain region; and
an interlayer dielectric over the first doped region, the second doped region, the first source/drain region and the second source/drain region.

3. The semiconductor device of claim 1, wherein the second source/drain region is at least partially extended within the bonding oxide.

4. The semiconductor device of claim 2, wherein the first doped region is doped with a same type of dopant as the second source/drain region, and the second doped region is doped with a same dopant as the first source/drain region.

5. The semiconductor device of claim 1, further comprising:
a doped region between the first source/drain region and the second source/drain region, wherein:
the first source/drain region and the second source/drain region are doped with different dopants, and
the doped region is doped with a same dopant as the first source/drain region.

6. The semiconductor device of claim 1, further comprising:
a doped region between the first source/drain region and the second source/drain region, wherein:
the first source/drain region and the second source/drain region are doped with a different type of dopant, and
the doped region is doped with a same dopant as the second source/drain region.

7. The semiconductor device of claim 1, further comprising:
a doped region between the first source/drain region and the second source/drain region, wherein:
the first source/drain region and the second source/drain region are doped with a same dopant, and
the doped region is doped with a different dopant as the first source/drain region and the second source/drain region.

8. The semiconductor device of claim 1, wherein the passive device region is an N+/n-well/P-well/P+ diode.

9. The semiconductor device of claim 1, further comprising:
a logic region, comprising:
a top transistor comprising:
a first top source/drain region;
a second top source/drain region;
a top transistor gate region;
a first backside contact connecting the second top source/drain region to a backside of the logic region; and
a frontside source/drain contact over the first top source/drain region, and
a bottom transistor comprising:
a first bottom source/drain region;
a second bottom source/drain region;
a bottom transistor gate region; and
a second backside source/drain contact below the second bottom source/drain region, and
a bonding oxide separating the top transistor and the bottom transistor.

10. The semiconductor device of claim 9, further comprising:
a via connecting the first bottom source/drain region to a back end of line on a frontside of the logic region.

11. A method for fabrication of a semiconductor device, the method comprising:
forming a passive device region, comprising:
forming a first source/drain region;
forming a second source/drain region;
forming a frontside contact over the first source/drain region;
forming a backside contact below the second source/drain region; and
forming a bonding oxide bonding the first source/drain region and the second source/drain region to a backside interlayer dielectric.

12. The method of claim 11, further comprising:
forming a first doped region and a second doped region between the first source/drain region and the second source/drain region; and
forming an interlayer dielectric over the first doped region, the second doped region, the first source/drain region and the second source/drain region.

13. The method of claim 11, further comprising:
extending partially the second source/drain region within the bonding oxide.

14. The method of claim 12, further comprising:
doping the first doped region with a same dopant as the second source/drain region; and
doping the second doped region with a same type of dopant as the first source/drain region.

15. The method of claim 11, further comprising:
forming a doped region between the first source/drain region and the second source/drain region;
doping the first source/drain region and the second source/drain region with different dopants; and
doping the doped region with a same dopant as the first source/drain region.

16. The method of claim 11, further comprising:
forming a doped region between the first source/drain region and the second source/drain region;
doping the first source/drain region and the second source/drain region are doped with different dopants; and
doping the doped region is doped with a same dopant as the second source/drain region.

17. The method of claim 11, further comprising:
forming a doped region between the first source/drain region and the second source/drain region;
forming the first source/drain region and the second source/drain region are doped with a same dopant; and
forming the doped region is doped with a different dopant as the first source/drain region and the second source/drain region.

18. The method of claim 11, further comprising:
forming a logic region, comprising:
forming a top transistor comprising:
forming a first top source/drain region;
forming a second top source/drain region;
forming a top transistor gate region;
forming a first backside contact connecting the second top source/drain region to a backside of the logic region; and
forming a frontside source/drain contact over the first top source/drain region, and
forming a bottom transistor comprising:
forming a first bottom source/drain region;
forming a second bottom source/drain region;
forming a bottom transistor gate region; and
forming a second backside source/drain contact below the second bottom source/drain region, and
forming a bonding oxide separating the top transistor and the bottom transistor.

19. The method of claim 18, further comprising:
establishing an electrical between the first bottom source/drain region and a back end of line on a frontside of the logic region through a via.

20. A semiconductor device, comprising:
a logic region, comprising:
a top transistor; and
a bottom, and
a passive device region comprising:
a first source/drain region;
a second source/drain region; and
a bonding oxide bonding the first source/drain region and the second source/drain region to a backside interlayer dielectric.
